(19) United States
(12) Patent Application Publication
(10) Pub. No.: US 2016/0093818 A1
(43) Pub. Date: Mar. 31, 2016

(54) Organometallic Complex, Light-Emitting Element, Light-Emitting Device, Electronic Device, and Lighting Device

(71) Applicant: Semiconductor Energy Laboratory Co., Ltd., Kanagawa-ken (JP)

(72) Inventors: Hideko INOUE, Atsugi (JP); Tomoya YAMAGUCHI, Atsugi (JP)

(73) Assignee: Semiconductor Energy Laboratory Co., Ltd., Kanagawa-ken (JP)

(21) Appl. No.: 14/867,535

(22) Filed: Sep. 28, 2015

(30) Foreign Application Priority Data
Sep. 30, 2014 (JP) 2014-201359

(51) Int. Cl. H01L 51/00; C09K 11/06; H01L 27/32; C07F 15/00

(52) U.S. Cl. CPC H01L 51/0085; C07F 15/0033; C09K 11/06; H01L 27/3244; H01L 51/5016

(57) ABSTRACT

An organometallic complex emitting light with high color purity. The organometallic complex is represented by General Formula (G1). In General Formula (G1), L represents a monoanionic ligand; R¹ represents a substituted or unsubstituted alkyl group having 1 to 10 carbon atoms or a substituted or unsubstituted aryl group having 6 to 13 carbon atoms; each of R² to R⁵ independently represents hydrogen, a substituted or unsubstituted alkyl group having 1 to 6 carbon atoms, or a substituted or unsubstituted phenyl group; the organometallic complex is monosubstituted, disubstituted, trisubstituted, tetrasubstituted, or unsubstituted by the R⁵; X represents O, S, or Se; and M represents a metal belonging to Group 9 or 10. When M represents a metal belonging to Group 9, in is 3 and n is 1, 2, or 3. When M represents a metal belonging to Group 10, m is 2 and n is 1 or 2.

### BACKGROUND OF THE INVENTION

1. Field of the Invention

One embodiment of the present invention relates to an object, a method, and a manufacturing method. In addition, one embodiment of the present invention relates to a process, a machine, manufacture, and a composition of matter. One embodiment of the present invention relates to a semiconductor device, a display device, a light-emitting device, a lighting device, a driving method thereof, and a manufacturing method thereof. One embodiment of the present invention relates to an organometallic complex. In particular, one embodiment of the present invention relates to an organometallic complex that is capable of converting a triplet excited state into light. In addition, one embodiment of the present invention relates to a light-emitting element, a light-emitting device, an electronic device, and a lighting device each including the organometallic complex.

2. Description of the Related Art

In recent years, a light-emitting element using a light-emitting organic compound or inorganic compound as a light-emitting material has been actively developed. In particular, a light-emitting element called an electroluminescence (EL) element has attracted attention as a next-generation flat panel display element because it has a simple structure in which a light-emitting layer containing a light-emitting material is provided between electrodes, and characteristics such as feasibility of being thinner and more lightweight and responsive to input signals and capability of driving with direct current at a low voltage. In addition, a display using such a light-emitting element has a feature that it is excellent in contrast and image quality, and has a wide viewing angle. Further, since such a light-emitting element is a plane light source, the light-emitting element is considered applicable to a light source such as a backlight of a liquid crystal display and an illumination device.

In the case where the light-emitting substance is an organic compound having a light-emitting property, the emission mechanism of the light-emitting element is a carrier-injection type. Specifically, by applying a voltage with a light-emitting layer provided between electrodes, electrons and holes injected from the electrodes recombine to raise the light-emitting substance to an excited state, and light is emitted when the substance in the excited state returns to the ground state. There are two types of the excited states which are possible: a singlet excited state (S*) and a triplet excited state (T*). In addition, the statistical generation ratio thereof in a light-emitting element is considered to be S*:T*=1:3.

In general, the ground state of a light-emitting organic compound is a singlet state. Light emission from a singlet excited state (S*) is referred to as fluorescence where electron transition occurs between the same multiplicities. In contrast, light emission from a triplet excited state (T*) is referred to as phosphorescence where electron transition occurs between different multiplicities. Here, in a compound emitting fluorescence (hereinafter referred to as a fluorescent compound), in general, phosphorescence cannot be observed at room temperature, and only fluorescence can be observed. Accordingly, the internal quantum efficiency (the ratio of generated photons to injected carriers) in a light-emitting element using a fluorescent compound is assumed to have a theoretical limit of 25% based on S*:T*=1:3.

In contrast, the use of a phosphorescent compound can increase the internal quantum efficiency to 100% in theory. In other words, emission efficiency can be 4 times as much as that of the fluorescent compound. For these reasons, in order to obtain a highly efficient light-emitting element, a light-emitting element using a phosphorescent compound has been developed actively recently. As the phosphorescent compound, an organometallic complex that has iridium or the like as a central metal have particularly attracted attention because of their high phosphorescence quantum yield. For example, an organometallic complex that has iridium as a central metal is disclosed as a phosphorescent material in Patent Documents 1 and 2.

An advantage of the use of the highly efficient light-emitting element is that power consumption of an electronic device using the light-emitting element can be reduced, for example. Energy issues have been discussed recently, and power consumption is becoming a major factor which affects consumer buying patterns; thus, power consumption is a very important element.

### REFERENCE

### Patent Document

[Patent Document 1] PCT International Publication No. WO 00/70655

[Patent Document 2] Japanese Published Patent Application No. 2013-53158

### SUMMARY OF THE INVENTION

Use of a compound capable of emitting phosphorescence can save power consumption of a light-emitting element; however, not only low power consumption but also high reliability and a long lifetime which enable long-term use of the light-emitting element, high color purity for producing great color, and the like are required for a light-emitting substance. A phosphorescent material that demonstrates these capabilities is needed.

In view of the above, an object of one embodiment of the present invention is to provide a novel substance that can emit phosphorescence. Another object is to provide a novel substance with high emission efficiency. Another object is to provide a novel substance emitting light with high color purity. Another object is to provide a novel substance emitting green phosphorescence. Another object is to provide a novel substance. Another object is to provide a light-emitting element, a light-emitting device, an electronic device, or a lighting device using the novel substance.

Another object is to provide a light-emitting element, a light-emitting device, an electronic device, or a lighting device with high emission efficiency. Another object is to provide a highly reliable light-emitting element, light-emitting device, electronic device, or lighting device. Another object is to provide a light-emitting element, a light-emitting device, an electronic device, or a lighting device with low power consumption. Another object is to provide a novel light-emitting element, light-emitting device, electronic device, or lighting device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

One embodiment of the present invention is an organometallic complex including a metal belonging to Group 9 or 10 and a ligand. In the organometallic complex, the ligand includes a benzofuro[2,3-b]pyridine skeleton or a benzothieno[2,3-b]pyridine skeleton, and a pyrimidine ring; carbon at the 2-position of the benzofuro[2,3-b]pyridine skeleton or the benzothieno[2,3-b]pyridine skeleton is bonded to the metal; nitrogen at the 3-position of the pyrimidine ring is bonded to the metal; carbon at the 3-position of the benzofuro[2,3-b]pyridine skeleton or the benzothieno[2,3-b]pyridine skeleton is bonded to carbon at the 4-position of the pyrimidine ring; and carbon at the 6-position of the pyrimidine ring is bonded to an alkyl group or an aryl group.

In the organometallic complex of one embodiment of the present invention, the alkyl group may be a substituted or unsubstituted alkyl group having 4 to 10 carbon atoms. The alkyl group may have a branched carbon chain. The metal may be iridium.

The organometallic complex of one embodiment of the present invention may further include a second ligand. The second ligand may be a monoanionic bidentate chelate ligand having a beta-diketone structure, a monoanionic bidentate chelate ligand having a carboxyl group, a monoanionic bidentate chelate ligand having a phenolic hydroxyl group, or a monoanionic bidentate chelate ligand in which two ligand elements are both nitrogen. The organometallic complex of one embodiment of the present invention may be used in an EL layer of a light-emitting element. In the light-emitting element of one embodiment of the present invention, the EL layer may emit phosphorescence.

Another embodiment of the present invention is an organometallic complex represented by General Formula (G1).

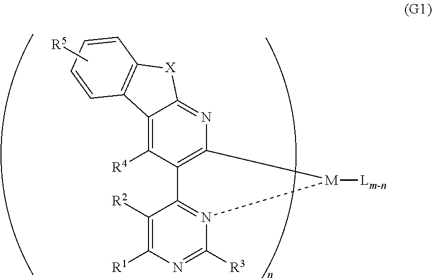

In General Formula (G1), L represents a monoanionic ligand; R¹ represents a substituted or unsubstituted alkyl group having 1 to 10 carbon atoms or a substituted or unsubstituted aryl group having 6 to 13 carbon atoms; each of R² to R⁵ independently represents hydrogen, a substituted or unsubstituted alkyl group having 1 to 6 carbon atoms, or a substituted or unsubstituted phenyl group; the organometallic complex is monosubstituted, disubstituted, trisubstituted, tetrasubstituted, or unsubstituted by the R⁵; X represents O, S, or Se; and M represents a metal belonging to Group 9 or 10. When M represents a metal belonging to Group 9, in is 3 and n is 1, 2, or 3. When M represents a metal belonging to Group 10, m is 2 and n is 1 or 2.

In the embodiment of the present invention, R¹ may represent a substituted or unsubstituted alkyl group having 4 to 10 carbon atoms; and L may represent a monoanionic bidentate chelate ligand having a beta-diketone structure, a monoanionic bidentate chelate ligand having a carboxyl group, a monoanionic bidentate chelate ligand having a phenolic hydroxyl group, or a monoanionic bidentate chelate ligand in which two ligand elements are both nitrogen. Note that L may be represented by any one of General Formulae (L1) to (L7).

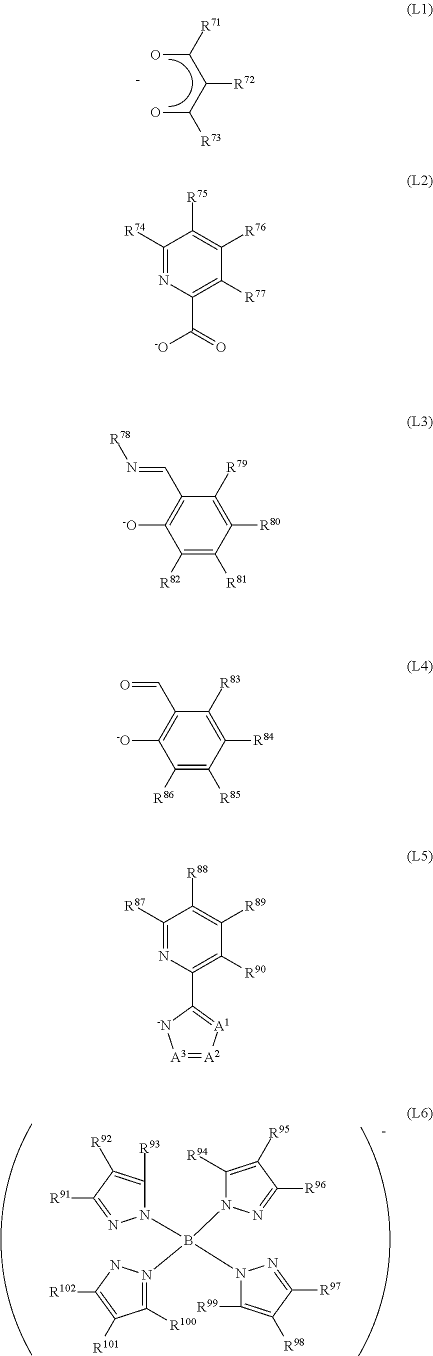

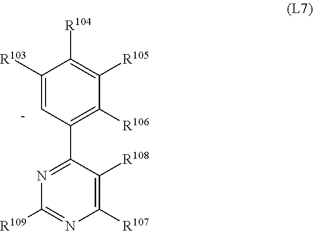

In the formulae, each of R⁷¹ to R¹⁰⁹ independently represents hydrogen, a substituted or unsubstituted alkyl group having 1 to 6 carbon atoms, a halogen group, a vinyl group, a substituted or unsubstituted haloalkyl group having 1 to 6 carbon atoms, a substituted or unsubstituted alkoxy group having 1 to 6 carbon atoms, or a substituted or unsubstituted alkylthio group having 1 to 6 carbon atoms. In addition, each of A¹ to A³ independently represents nitrogen, sp² carbon bonded to hydrogen, or sp² carbon bonded to a substituent R. The substituent R represents an alkyl group having 1 to 6 carbon atoms, a halogen group, a haloalkyl group having 1 to 6 carbon atoms, or a phenyl group.

Another embodiment of the present invention is an organometallic complex represented by General Formula (G2).

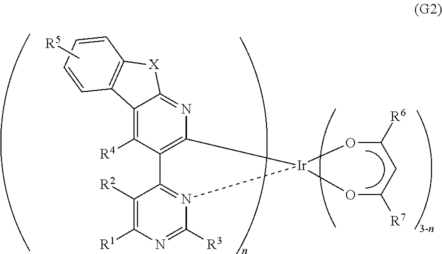

In General Formula (G2), R¹ represents a substituted or unsubstituted alkyl group having 1 to 10 carbon atoms or a substituted or unsubstituted aryl group having 6 to 13 carbon atoms; each of R² to R⁷ independently represents hydrogen, a substituted or unsubstituted alkyl group having 1 to 6 carbon atoms, or a substituted or unsubstituted phenyl group; the organometallic complex is monosubstituted, disubstituted, trisubstituted, tetrasubstituted, or unsubstituted by the R⁵; X represents O, S, or Se; and n is 1, 2, or 3.

Another embodiment of the present invention is an organometallic complex represented by Structural Formula (100).

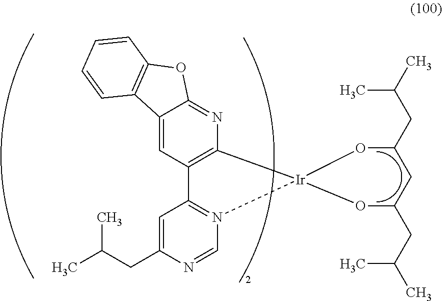

Another embodiment of the present invention is an organometallic complex represented by Structural Formula (110).

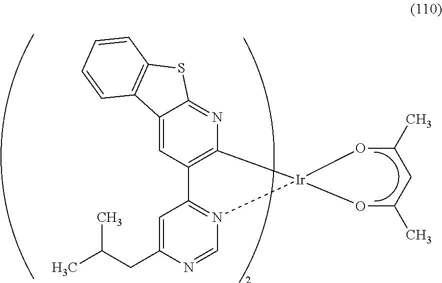

Another embodiment of the present invention is a light-emitting element in which the organometallic complex of one embodiment of the present invention is used in an EL layer. The EL layer may emit phosphorescence. Another embodiment of the present invention is a display module including the light-emitting element of one embodiment of the present invention and a driver. Another embodiment of the present invention is a lighting device including the light-emitting element of one embodiment of the present invention and an operation switch. Another embodiment of the present invention is a light-emitting device including the light-emitting element of one embodiment of the present invention and an operation switch. Another embodiment of the present invention is a display device including the light-emitting element of one embodiment of the present invention in a display portion, a driver, and an operation switch. Another embodiment of the present invention is an electronic device including the light-emitting element of one embodiment of the present invention and a power supply switch.

The organometallic complex of one embodiment of the present invention can emit phosphorescence. The organometallic complex of one embodiment of the present invention has high heat resistance and high reliability because a pyridine ring bonded to the central metal is fused. However, the conjugation is extended because of the fusion, which makes the emission wavelength longer. In the pyridine ring, HOMO appears around an atom adjacent to a carbon atom bonded to the metal, and the atom adjacent to the carbon atom is an electron-withdrawing nitrogen atom; thus, HOMO is stabilized and triple excitation energy is increased. In particular, the organometallic complex of one embodiment of the present invention has a pyrimidine skeleton with high emission efficiency, and the yellow emission wavelength derived from the pyrimidine skeleton is shortened due to the HOMO stabilization. Therefore, the organometallic complex of one embodiment of the present invention emits green light with high color purity.

With one embodiment of the present invention, a novel substance that can emit phosphorescence, a novel substance with high emission efficiency, a novel substance emitting light with high color purity, and/or a novel substance emitting green phosphorescence can be provided. In addition, a light-emitting element, a light-emitting device, an electronic device, or a lighting device using the novel substance can be provided.

Alternatively, a light-emitting element, a light-emitting device, an electronic device, or a lighting device with high emission efficiency can be provided. Alternatively, a light-emitting element, a light-emitting device, an electronic device, or a lighting device with high reliability can be provided. Alternatively, a light-emitting element, a light-emitting device, an electronic device, or a lighting device with low power consumption can be provided. Alternatively, a novel substance can be provided. Alternatively, a novel light-emitting element, a novel light-emitting device, a novel electronic device, or a novel lighting device can be provided.

Note that the description of these effects does not disturb the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

FIGS. 1A to 1C each illustrate a light-emitting element of one embodiment of the present invention.

FIGS. 2A to 2D illustrate a passive-matrix light-emitting device.

FIG. 3 illustrates a passive-matrix light-emitting device.

FIGS. 4A and 4B illustrate an active matrix light-emitting device.

FIGS. 5A to 5E illustrate electronic devices.

FIGS. 6A and 6B illustrate lighting devices.

FIG. 7 illustrates a lighting device.

FIGS. 8A and 8B are NMR charts of [Ir(iBubfpypm)₂(divm)].

FIGS. 9A and 9B are NMR charts of [Ir(iBubfpypm)₂(divm)].

FIG. 10 shows an ultraviolet-visible (UV) absorption spectrum and an emission spectrum (PL) of [Ir(iBubfpypm)₂(divm)].

FIGS. 11A and 11B are NMR charts of [Ir(iBubtpypm)₂(acac)].

FIGS. 12A and 12B are NMR charts of [Ir(iBubtpypm)₂(acac)].

FIG. 13 shows an ultraviolet-visible (UV) absorption spectrum and an emission spectrum (PL) of [Ir(iBubtpypm)₂(acac)].

FIG. 14 illustrates HOMO distribution of [Ir(iPrppm)₂(acac)].

FIGS. 15A to 15D illustrate lighting devices.

FIGS. 16A and 16B illustrate an example of a touch panel.

FIGS. 17A and 17B illustrate an example of a touch panel.

FIGS. 18A and 18B illustrate an example of a touch panel.

FIGS. 19A and 19B are a block diagram and a timing chart of a touch sensor.

FIG. 20 is a circuit diagram of a touch sensor.

### DETAILED DESCRIPTION OF THE INVENTION

Embodiments of the present invention will be described below. Note that it is easily understood by those skilled in the art that modes and details disclosed herein can be modified in various ways without departing from the spirit and scope of the present invention. Therefore, the present invention is not construed as being limited to the description of the following embodiments.

Note that the terms “film” and “layer” can be interchanged with each other depending on the case or circumstances. For example, the term “conductive layer” can be changed into the term “conductive film” in some cases. Also, the term “insulating film” can be changed into the term “insulating layer” in some cases.

### Embodiment 1

In this embodiment, an organometallic complex used for a light-emitting element of one embodiment of the present invention is described.

One embodiment of the present invention is an organometallic complex represented by General Formula (G1).

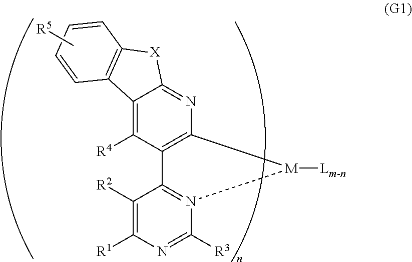

In General Formula (G1), L represents a monoanionic ligand; R¹ represents a substituted or unsubstituted alkyl group having 1 to 10 carbon atoms or a substituted or unsubstituted aryl group having 6 to 13 carbon atoms; each of R² to R⁵ independently represents hydrogen, a substituted or unsubstituted alkyl group having 1 to 6 carbon atoms, or a substituted or unsubstituted phenyl group; the organometallic complex is monosubstituted, disubstituted, trisubstituted, tetrasubstituted, or unsubstituted by the R⁵; X represents O, S, or Se; and M represents a metal belonging to Group 9 or 10. When M represents a metal belonging to Group 9, in is 3 and n is 1, 2, or 3. When M represents a metal belonging to Group 10, in is 2 and n is 1 or 2.

First, a ligand of an organometallic complex of one embodiment of the present invention is described in Embodiment 1.

### <<Synthesis Method of Pyrimidine Derivative Represented by General Formula (G0)>>

A pyrimidine derivative represented by General Formula (G0) is used as the ligand of the organometallic complex represented by General Formula (G1). The pyrimidine derivative represented by General Formula (G0) can be synthesized by Synthesis Scheme (A) or (A′) shown below. In Synthesis Scheme (A), Q represents halogen; R³¹ represents a single bond, a methylene group, an ethylidene group, a propylidene group, an isopropylidene group, or the like; each of R³² to R³⁵ independently represents a hydrogen atom or an alkyl group having 1 to 3 carbon atoms; and R³³ and R³⁵ may be bonded to each other through a carbon chain to form a ring.

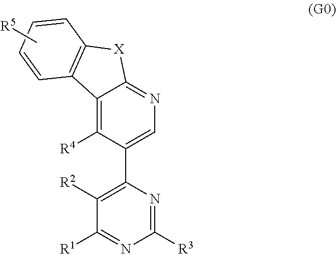

In General Formula (G0), R¹ represents a substituted or unsubstituted alkyl group having 1 to 10 carbon atoms or a substituted or unsubstituted aryl group having 6 to 13 carbon atoms; each of R² to R⁵ independently represents hydrogen, a substituted or unsubstituted alkyl group having 1 to 6 carbon atoms, or a substituted or unsubstituted phenyl group; the pyrimidine derivative is monosubstituted, disubstituted, trisubstituted, tetrasubstituted, or unsubstituted by the R⁵; and X represents O, S, or Se;

For example, as illustrated in Synthesis Scheme (A), the pyrimidine derivative represented by General Formula (G0) can be obtained by coupling a boronic acid, a boronate ester, or a cyclic-triolborate salt (A1) with a halogenated pyrimidine compound (A2). As the cyclic-triolborate salt, a lithium salt, a potassium salt, or a sodium salt may be used.

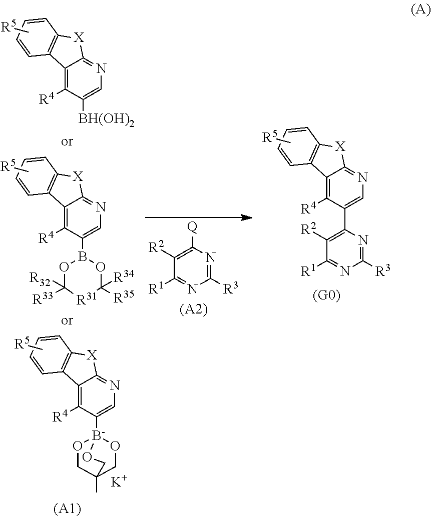

Alternatively, the organometallic complex represented by General Formula (G0) can be obtained by reacting a 1,3-diketone derivative (A1′) with diamine (A2′) as shown in Synthesis Scheme (A′).

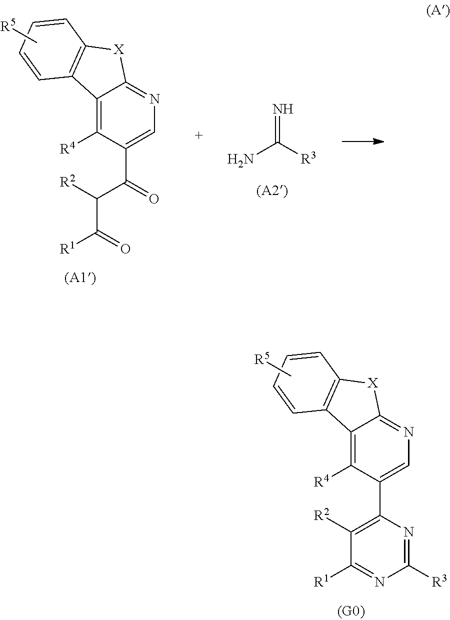

Since a wide variety of compounds (A1), (A2), (A1′), and (A2′) are commercially available or their synthesis is feasible, a great variety of the pyrimidine derivative represented by General Formula (G0) can be synthesized. Thus, a feature of the organometallic complex of one embodiment of the present invention is the abundance of ligand variations.

### <<Synthesis Method 1 of Organometallic Complex of One Embodiment of the Present Invention Represented by General Formula (G1)>>

Next, a method for synthesizing the organometallic complex of one embodiment of the present invention represented by General Formula (G1), which is formed using the pyridine derivative represented by General Formula (G0), is described. First, a method for synthesizing an organometallic complex represented by General Formula (G1-1) where m−n=1 is described among the organometallic complexes represented by General Formula (G1).

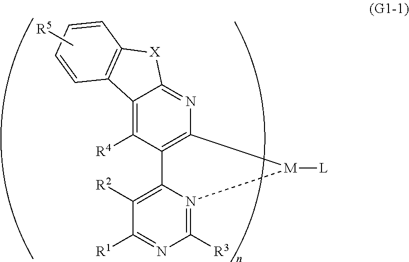

First, as shown in Synthesis Scheme (B-1), the pyrimidine derivative represented by General Formula (G0) and a metal compound containing halogen (e.g., palladium chloride, iridium chloride, iridium bromide, iridium iodide, or potassium tetrachloroplatinate) are heated in an inert gas atmosphere by using no solvent, an alcohol-based solvent (e.g., glycerol, ethylene glycol, 2-methoxyethanol, or 2-ethoxyethanol) alone, or a mixed solvent of water and one or more kinds of such alcohol-based solvents, whereby a dinuclear complex (P), which is one type of an organometallic complex having a halogen-bridged structure and is a novel substance, can be obtained. There is no particular limitation on a heating means, and an oil bath, a sand bath, or an aluminum block may be used. Alternatively, microwaves can be used as the heating means.

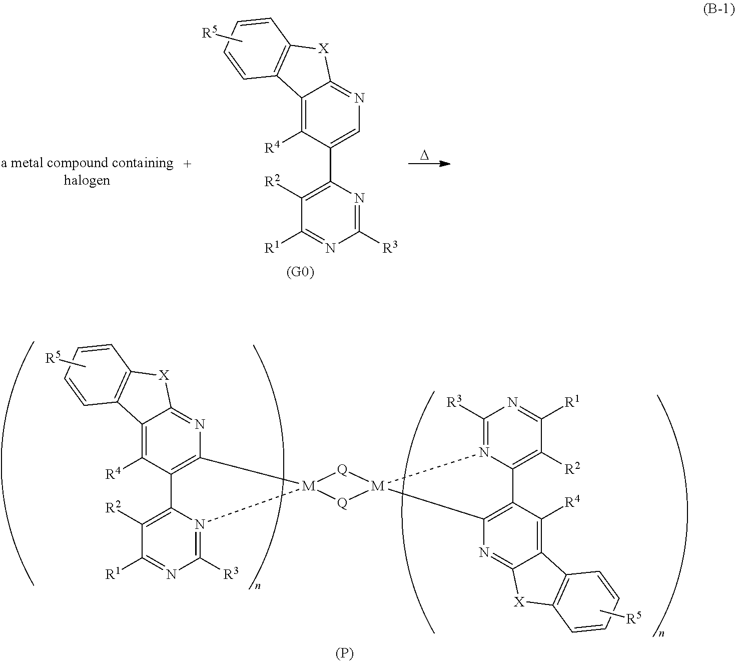

In Synthesis Scheme (B-1), Q represents halogen; R¹ represents a substituted or unsubstituted alkyl group having 1 to 10 carbon atoms or a substituted or unsubstituted aryl group having 6 to 13 carbon atoms; each of R² to R⁵ independently represents hydrogen, a substituted or unsubstituted alkyl group having 1 to 6 carbon atoms, or a substituted or unsubstituted phenyl group; the organometallic complex is monosubstituted, disubstituted, trisubstituted, tetrasubstituted, or unsubstituted by the R⁵; X represents O, S, or Se; and M represents a metal belonging to Group 9 or 10. When M represents a metal belonging to Group 9, n is 2. When M represents a metal belonging to Group 10, n is 1.

Furthermore, as shown in Synthesis Scheme (B-2), the dinuclear complex (P) obtained through Synthesis Scheme (B-1) is reacted with HL which is a material of a monoanionic ligand in an inert gas atmosphere, whereby a proton of HL is separated and L coordinates to the metal M. Thus, the organometallic complex of one embodiment of the present invention which is represented by General Formula (G1-1) can be obtained. There is no particular limitation on a heating means, and an oil bath, a sand bath, or an aluminum block may be used. Alternatively, microwaves can be used as the heating means. In Synthesis Scheme (B-2), M represents a metal belonging to Group 9 or 10. When M represents a metal belonging to Group 9, n is 2. When M represents a metal belonging to Group 10, n is 1.

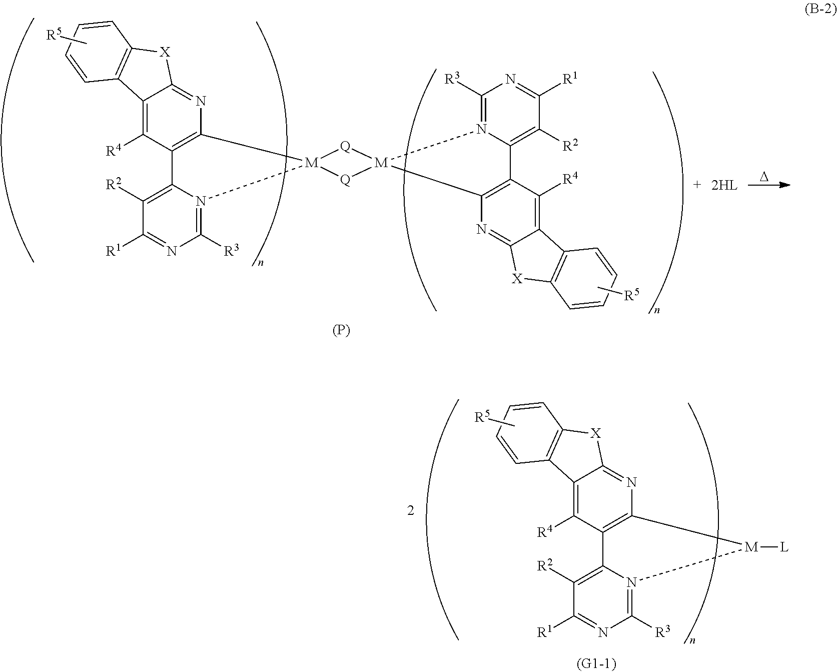

In Synthesis Scheme (B-2), L represents a monoanionic ligand; Q represents halogen; R¹ represents a substituted or unsubstituted alkyl group having 1 to 10 carbon atoms or a substituted or unsubstituted aryl group having 6 to 13 carbon atoms; each of R² to R⁵ independently represents hydrogen, a substituted or unsubstituted alkyl group having 1 to 6 carbon atoms, or a substituted or unsubstituted phenyl group; the organometallic complex is monosubstituted, disubstituted, trisubstituted, tetrasubstituted, or unsubstituted by the R⁵ is 0 to 4; and X represents O, S, or Se.

In one embodiment of the present invention, a substituent is preferably introduced to the 6-position (i.e., the position of R¹) of a pyrimidine ring in order that an ortho-metalated complex in which the pyrimidine derivative is a ligand is obtained. In particular, a substituted or unsubstituted alkyl group having 4 to 10 carbon atoms or a substituted or unsubstituted aryl group having 6 to 13 carbon atoms is preferably used as R¹. This is because, as compared to the case where hydrogen or an alkyl group having 1 to 3 carbon atoms is used as R¹, decomposition of the halogen-bridged dinuclear metal complex synthesized by Synthesis Scheme (B-1) during reaction represented by Synthesis Scheme (B-2) is suppressed, and a drastically high yield can be achieved. This increases the resolvability of the organometallic complexes and facilitates purification using a solution, which can increase the purity of a material. Therefore, when the ortho-metalated complex is used as a dopant of a light-emitting element, the light-emitting element has stable characteristics and high reliability. In addition, when the ortho-metalated complex is used as a dopant of a light-emitting element, the dispersibility of the dopant can be improved and quenching can be prevented, increasing the light-emitting efficiency.

Note that it is preferable that L that is the monoanionic ligand in General Formula (G1-1) be any of a monoanionic bidentate chelate ligand having a beta-diketone structure, a monoanionic bidentate chelate ligand having a carboxyl group, a monoanionic bidentate chelate ligand having a phenolic hydroxyl group, and a monoanionic bidentate chelate ligand in which two ligand elements are both nitrogen. A monoanionic bidentate chelate ligand having a beta-diketone structure is particularly preferable because a solubility of an organometallic complex in an organic solvent becomes higher and purification becomes easier. Furthermore, a beta-diketone structure is preferably included because an organometallic complex with high emission efficiency can be obtained. Moreover, inclusion of a beta-diketone structure has advantages such as a higher sublimation property and excellent evaporativity.

The monoanionic ligand is preferably any of ligands represented by General Formulae (L1) to (L7). These ligands are useful because they have high coordinative ability and are available at low price.

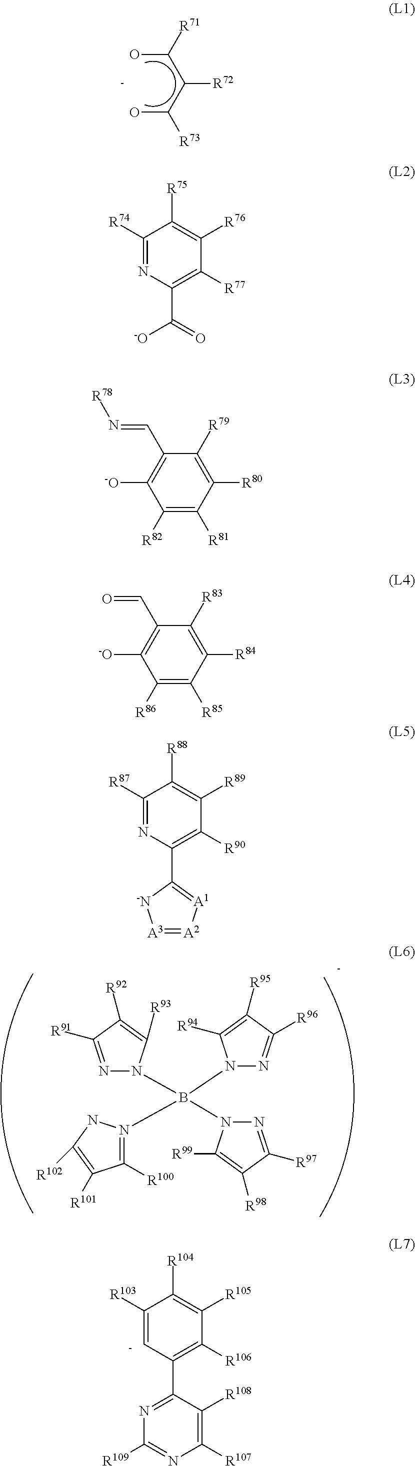

### <<Synthesis Method 2 of Organometallic Complex of One Embodiment of the Present Invention Represented by General Formula (G1)>>

Next, a method for synthesizing an organometallic complex represented by General Formula (G1-2) where m−n=0 is described among the organometallic complexes represented by General Formula (G1).

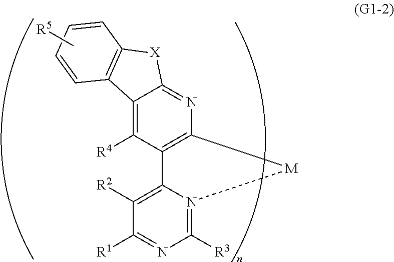

As shown in Synthesis Scheme (C), by mixing the pyrimidine derivative represented by General Formula (G0) is mixed with a compound of a Group 9 metal or a Group 10 metal that contains a halogen (e.g., rhodium chloride hydrate, palladium chloride, iridium chloride hydrate, ammonium hexachloroiridate, or potassium tetrachloroplatinate) or an organometallic complex compound of a Group 9 metal or a Group 10 metal (e.g., an acetylacetonate complex or a diethylsulfide complex), and the mixture is then heated, whereby the organometallic complex having the structure represented by General Formula (G1-2) can be obtained. This heating process may be performed after the pyrimidine derivative represented by General Formula (G0) and the compound of a Group 9 metal or a Group 10 metal that contains a halogen or the organometallic complex compound of a Group 9 metal or a Group 10 metal are dissolved in an alcohol-based solvent (e.g., glycerol, ethylene glycol, 2-methoxyethanol, or 2-ethoxyethanol). In Synthesis Scheme (C), M represents a metal belonging to Group 9 or 10. When M represents a metal belonging to Group 9, n is 3. When M represents a metal belonging to Group 10, n is 2.

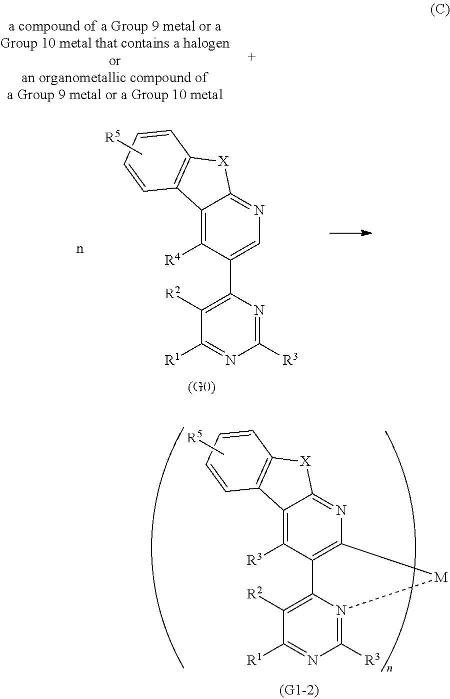

In Synthesis Scheme (C), R¹ represents a substituted or unsubstituted alkyl group having 1 to 10 carbon atoms or a substituted or unsubstituted aryl group having 6 to 13 carbon atoms; each of R² to R⁵ independently represents hydrogen, a substituted or unsubstituted alkyl group having 1 to 6 carbon atoms, or a substituted or unsubstituted phenyl group; the organometallic complex is monosubstituted, disubstituted, trisubstituted, tetrasubstituted, or unsubstituted by the R⁵; and X represents O, S, or Se.

In one embodiment of the present invention, a substituent is preferably introduced to the 6-position (i.e., the position of R¹) of a pyrimidine ring in order to obtain an ortho-metalated complex in which a pyrimidine derivative is a ligand. In particular, a substituted or unsubstituted alkyl group having 4 to 10 carbon atoms or a substituted or unsubstituted aryl group having 6 to 13 carbon atoms is used as R¹. Therefore, as compared to the case where hydrogen is used as R¹, the yield in Synthesis Scheme C can be higher.

In General Formulae (G0), (G1), (G1-1), and (G1-2), specific examples of the substituted or unsubstituted alkyl group having 1 to 10 carbon atoms as R¹ and the substituted or unsubstituted alkyl group having 1 to 6 carbon atoms as R² to R⁵ include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, a 2,3-dimethylbutyl group, an octyl group, an isooctyl group, a sec-octyl group, a tert-octyl group, a nonyl group, an isononyl group, a sec-nonyl group, a tert-nonyl group, a decanyl group, an isodecanyl group, a sec-decanyl group, a tert-decanyl group, an undecanyl group, and an isoundecanyl group. Specific examples of the substituted or unsubstituted aryl group having 6 to 13 carbon atoms include a phenyl group, a tolyl group, a xylyl group, a biphenyl group, an indenyl group, a naphthyl group, and a fluorenyl group.

Next, typical examples of the organometallic complex are shown by Chemical Formulae (100) to (111), (200), (300), and (400) to (403). Note that the compounds described in this embodiment are not limited to the examples shown below.

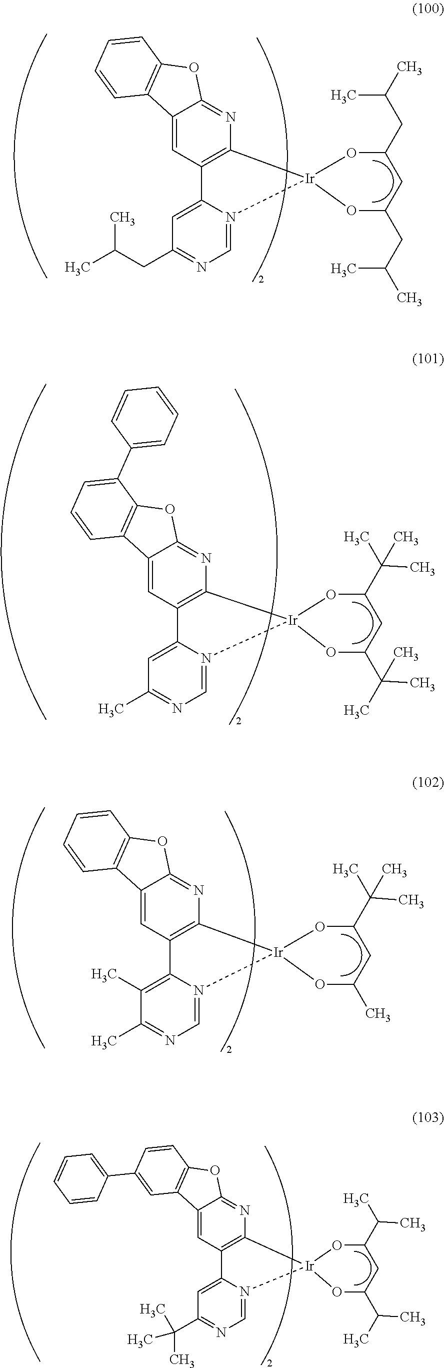

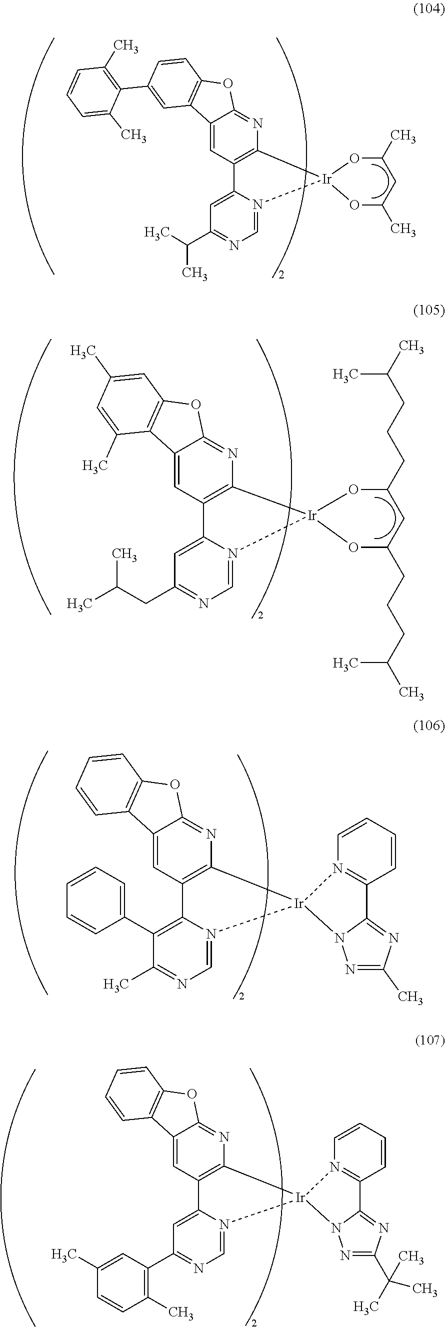

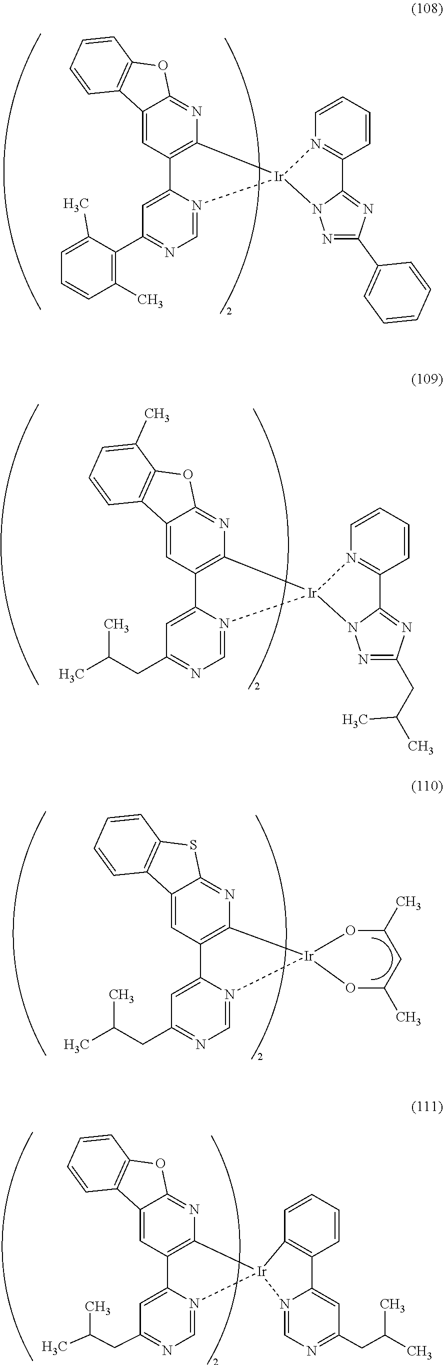

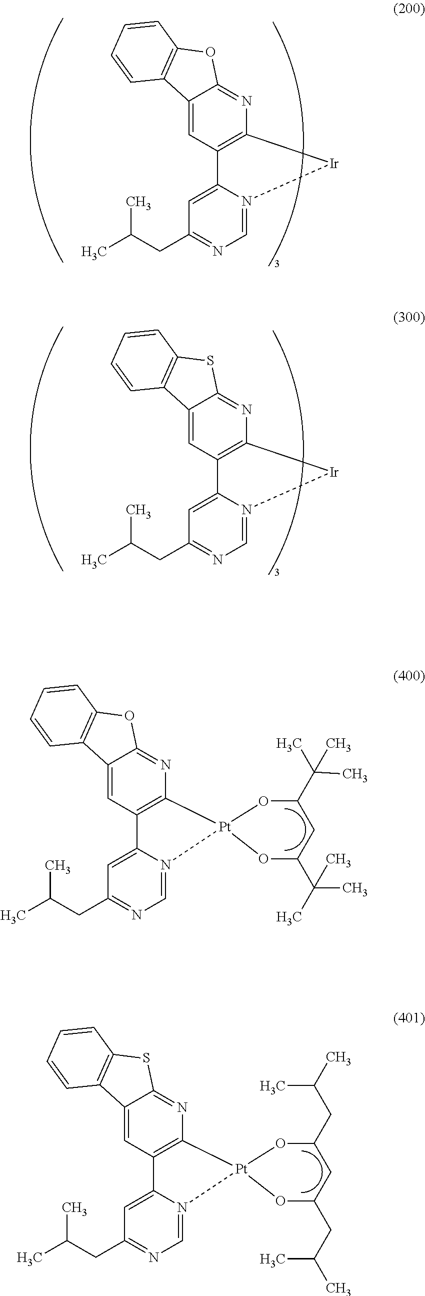

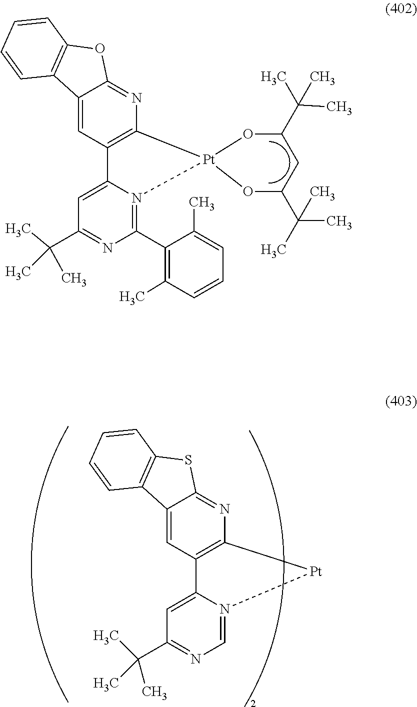

The organometallic complex of one embodiment of the present invention described above emits light having a sharp peak with a narrow half width in the green emission wavelength. Thus, a light-emitting element having a high color rendering property can be realized. Since the light-emitting element in this embodiment includes the organometallic complex of one embodiment of the present invention, a light-emitting element with high emission efficiency can be realized. In addition, a light-emitting element with low power consumption can be realized. Thus, a light-emitting element with high reliability can be realized.

In Embodiment 1, one embodiment of the present invention has been described. Other embodiments of the present invention are described in Embodiments 2 to 9. Note that the present invention is not limited to the above examples. In other words, various embodiments of the invention are described in this embodiment and the other embodiments, and one embodiment of the present invention is not limited to a particular embodiment. Although an example in which one embodiment of the present invention is applied to a light-emitting element is described, one embodiment of the present invention is not limited thereto. Depending on circumstances or conditions, one embodiment of the present invention may be applied to objects other than a light-emitting element. Depending on circumstances or conditions, one embodiment of the present invention is not necessarily applied to a light-emitting element. Although an example in which a metal belonging to Group 9 or 10 is used in one embodiment of the present invention is described, one embodiment of the present invention is not limited thereto. Depending on circumstances or conditions, a metal other than the metal belonging to Group 9 or 10 may be used in one embodiment of the present invention. Alternatively, depending on circumstances or conditions, the metal belonging to Group 9 or 10 is not necessarily used in one embodiment of the present invention. Although an example of a light-emitting element that uses a triplet level (an energy difference between a triplet excited state and a singlet excited state) for its emission is described, one embodiment of the present invention is not limited thereto. Depending on circumstances or conditions, a light-emitting element other than the light-emitting element using a triplet level for its emission may be used in one embodiment of the present invention. Alternatively, depending on circumstances or conditions, the triplet level is not necessarily used for emission in one embodiment of the present invention.

### Embodiment 2

Described in this embodiment is shortening of emission wavelength due to a molecular structure in the organometallic complex of one embodiment of the present invention.

Although fusion of a benzene ring to which the metal is bonded can improve heat resistance, conjugation is extended due to the fusion in many cases, which makes an emission wavelength longer. Molecular orbital calculations of a benzene ring to which the metal is bonded were performed in the manner described below. The result reveals that HOMO appears around a carbon atom bonded to the metal is bonded and an atom adjacent to the carbon atom. It is thought that stabilization of HOMO can make an emission wavelength short while high heat resistance due to the fused structure is kept.

In other words, when the atom adjacent to the carbon atom bonded to the metal is an electron-withdrawing nitrogen atom, HOMO is stabilized and the triplet excitation energy is increased. Therefore, the organometallic complex of one embodiment of the present invention, in which an atom adjacent to a carbon atom bonded to the metal is an electron-withdrawing nitrogen atom, can make an emission wavelength of yellow light derived from a pyrimidine skeleton short by being combined with a pyrimidine skeleton with high emission efficiency. Therefore, such a structure is suitable as a basic skeleton of a green-light-emitting material with high color purity, which is required for displays.

Here, distribution of HOMO obtained by the calculations is described. Note that the organometallic complex represented by Structural Formula (001), bis[2-(6-isopropyl-4-pyrimidinyl-κN3)phenyl-κC](2,4-pentanedionato-κ²O,O′)iridium(I II) (abbreviation: [Ir(iPrppm)₂(acac)]), was used.

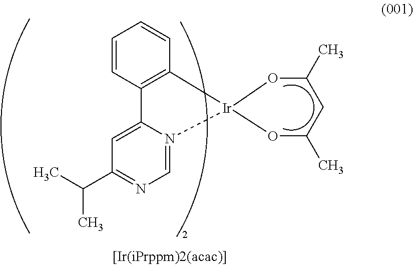

### <<Calculation Example>>

First, the most stable structure of the organometallic complex [Ir(iPrppm)₂(acac)] (abbreviation) in the singlet ground state (S0) was calculated using the density functional theory (DFT). In the DFT, the total energy is represented as the sum of potential energy, electrostatic energy between electrons, electronic kinetic energy, and exchange-correlation energy including all the complicated interactions between electrons. Also in the DFT, since an exchange-correlation interaction is approximated by a functional (a function of another function) of one electron potential represented in terms of electron density, calculations are performed at high speed. Here, B3PW91, which is a hybrid functional, was used to specify the weight of each parameter related to exchange-correlation energy.

As basis functions, 6-311G (a basis function of a triple-split valence basis set using three contraction functions for a valence orbital) was applied to each of H, C, and N atoms, and LanL2DZ was applied to an Ir atom. By the above basis function, for example, orbits of is to 3s are considered in the case of hydrogen atoms while orbits of 1 s to 4s and 2p to 4p are considered in the case of carbon atoms. Furthermore, to improve calculation accuracy, the p function and the d function, respectively, were added as polarization basis sets to hydrogen atoms and atoms other than hydrogen atoms. Note that Gaussian 09 was used as a quantum chemistry computational program. A high performance computer (ICE X, manufactured by SGI Japan, Ltd.) was used for the calculation.

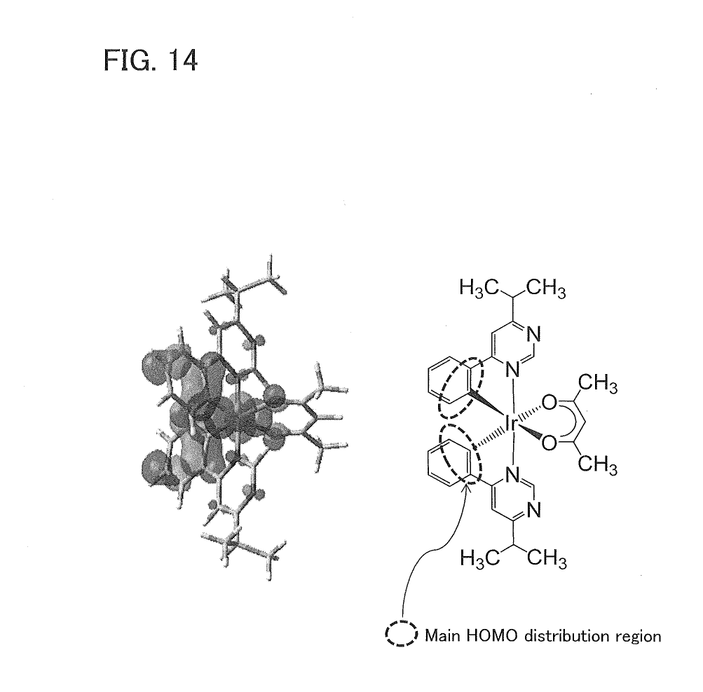

FIG. 14 shows distribution of the HOMO of the organometallic complex [Ir(iPrppm)₂(acac)] (abbreviation), which was obtained by the above calculation method.

FIG. 14 reveals that HOMO appears around a carbon atom bonded to the metal and an atom adjacent to the carbon atom. Therefore, the organometallic complex of one embodiment of the present invention, in which the atom adjacent to the carbon atom bonded to the metal is an electron-withdrawing nitrogen atom, can have relatively stable HOMO. Accordingly, in the organometallic complex of one embodiment of the present invention, the triplet excitation energy is increased; thus, an emission wavelength of yellow light derived from a pyrimidine skeleton can be shortened, and the organometallic complex can emit green light with high color purity.

### Embodiment 3

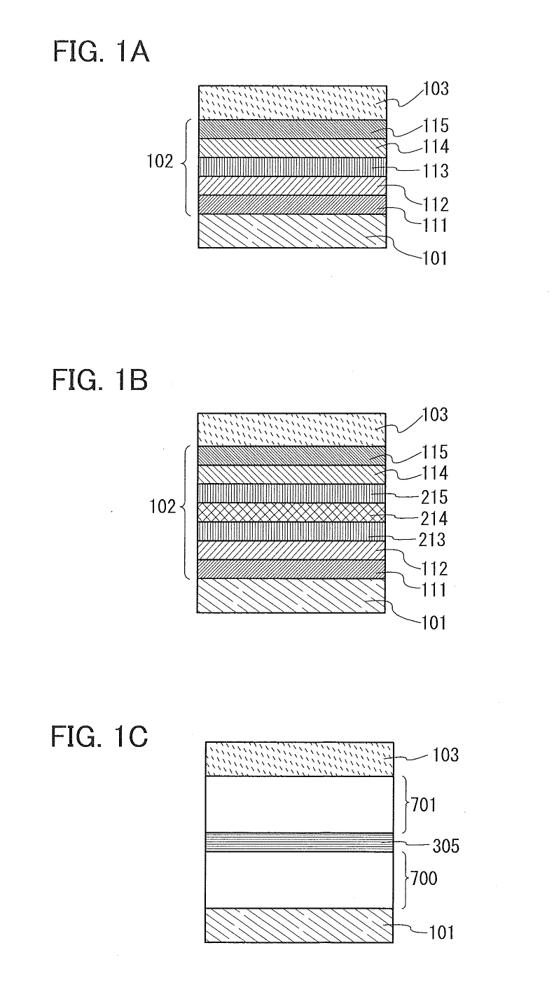

In Embodiment 3, as one embodiment of the present invention, a light-emitting element in which an organometallic complex described in Embodiment 1 is used for a light-emitting layer will be described with reference to FIG. 1A.

FIG. 1A illustrates a light-emitting element having an EL layer 102 between a first electrode 101 and a second electrode 103. The EL layer 102 includes a light-emitting layer 113. The light-emitting layer 113 includes an organometallic complex described in Embodiment 1.

By application of a voltage to such a light-emitting element, holes injected from the first electrode 101 side and electrons injected from the second electrode 103 side recombine in the light-emitting layer 113 to raise the organometallic complex to an excited state. Then, light is emitted when the organometallic complex in the excited state returns to the ground state. Thus, the organometallic complex of one embodiment of the present invention functions as a light-emitting substance in the light-emitting element. Note that in the light-emitting element described in this embodiment, the first electrode 101 functions as an anode and the second electrode 103 functions as a cathode.

For the first electrode 101 functioning as an anode, any of metals, alloys, electrically conductive compounds, mixtures thereof, and the like which has a high work function (specifically, a work function of 4.0 eV or more) is preferably used. Specific examples are indium oxide-tin oxide (ITO:indium tin oxide), indium oxide-tin oxide containing silicon or silicon oxide, indium oxide-zinc oxide (IZO:indium zinc oxide), indium oxide containing tungsten oxide and zinc oxide, and the like. Other than these, gold, platinum, nickel, tungsten, chromium, molybdenum, iron, cobalt, copper, palladium, titanium, or the like can be used.

When a layer included in the EL layer 102 which is formed in contact with the first electrode 101 is formed using a later described composite material formed by combining an organic compound and an electron acceptor (acceptor), as a substance used for the first electrode 101, any of a variety of metals, alloys, and electrically-conductive compounds, a mixture thereof, and the like can be used regardless of the work function; for example, aluminum, silver, an alloy containing aluminum (e.g., Al—Si), or the like can also be used.

The first electrode 101 can be formed by, for example, a sputtering method, an evaporation method (including a vacuum evaporation method), or the like.

The EL layer 102 formed over the first electrode 101 has at least the light-emitting layer 113 and is formed to include an organometallic complex described in Embodiment 1. For part of the EL layer 102, a variety of substances can be used, and either a low molecular compound or a high molecular compound can be used. Note that substances forming the EL layer 102 may consist of organic compounds or may include an inorganic compound as a part.

As illustrated in FIG. 1A, the EL layer 102 is formed by stacking as appropriate the hole-injection layer 111 containing a substance having a high hole-injection property, the hole-transport layer 112 containing a substance having a high hole-transport property, the electron-transport layer 114 containing a substance having a high electron-transport property, the electron-injection layer 115 containing a substance having a high electron-injection property, and the like in combination in addition to the light-emitting layer 113.

The hole-injection layer 111 is a layer containing a substance having a high hole-injection property. Examples of a substance having a high hole-injection property which can be used are metal oxides, such as molybdenum oxide, titanium oxide, vanadium oxide, rhenium oxide, ruthenium oxide, chromium oxide, zirconium oxide, hafnium oxide, tantalum oxide, silver oxide, tungsten oxide, and manganese oxide. Other examples of a substance that can be used are phthalocyanine-based compounds, such as phthalocyanine (abbreviation: H₂Pc) and copper(II) phthalocyanine (abbreviation: CuPc).

Other examples of a substance that can be used are aromatic amine compounds which are low molecular organic compounds, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), and 3-[N-(1-naphthyl)-N-(9-phenylcarbazol-3-yl)amino]-9-phenylcarbazole (abbreviation: PCzPCN1).

Still other examples of a substance that can be used are high molecular compounds (e.g., oligomers, dendrimers, and polymers), such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-M-phenylamino}phenyl)methacrylamide] (abbreviation: PTPDMA), and poly[N,N′-bis(4-butylphenyl)-N,N′-bis(phenyl)benzidine] (abbreviation: Poly-TPD), and high molecular compounds to which acid is added, such as poly(3,4-ethylenedioxythiophene)/poly(styrenesulfonic acid) (PEDOT/PSS), or polyaniline/poly(styrenesulfonic acid) (PAni/PSS).

For the hole-injection layer 111, the composite material formed by combining an organic compound and an electron acceptor (acceptor) may be used. Such a composite material, in which holes are generated in the organic compound by the electron acceptor, has an excellent hole injection and transport properties. In this case, the organic compound is preferably a material excellent in transporting the generated holes (a substance having a high hole-transport property).

Examples of the organic compound used for the composite material are a variety of compounds, such as aromatic amine compounds, carbazole derivatives, aromatic hydrocarbons, and high molecular compounds (e.g., oligomers, dendrimers, and polymers). The organic compound used for the composite material is preferably organic compounds having a high hole-transport property, and specifically preferably a substance having a hole mobility of 10⁻⁶ cm²/Vs or more. Note that other than these substances, any substance that has a property of transporting more holes than electrons may be used. Organic compounds that can be used for the composite material will be specifically described below.

Examples of an organic compound that can be used for the composite material are aromatic amine compounds, such as TDATA, MTDATA, DPAB, DNTPD, DPA3B, PCzPCA1, PCzPCA2, PCzPCN1, 4,4′-bis[N-(1-naphthyl)-N-phenylamino]biphenyl (abbreviation: NPB or α-NPD), N,N′-bis(3-methylphenyl)-N,N′-diphenyl-[1,1′-biphenyl]-4,4-diamine (abbreviation: TPD), and 4-phenyl-4′-(9-phenylfluoren-9-yl)triphenylamine (abbreviation: BPAFLP), and carbazole derivatives, such as 4,4′-di(N-carbazolyl)biphenyl (abbreviation: CBP), 1,3,5-tris[4-(N-carbazolyl)phenyl]benzene (abbreviation: TCPB), 9-[4-(N-carbazolyl)phenyl]-10-phenylanthracene (abbreviation: CzPA), 9-phenyl-3-[4-(10-phenyl-9-anthryl)phenyl]-9H-carbazole (abbreviation: PCzPA), and 1,4-bis[4-(N-carbazolyl)phenyl]-2,3,5,6-tetraphenylbenzene.

Other examples of an organic compound that can be used are aromatic hydrocarbon compounds, such as 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyDanthracene (abbreviation: DMNA), 9,10-bis[2-(1-naphthyl)phenyl]-2-tert-butylanthracene, 9,10-bis[2-(1-naphthyl)phenyl]anthracene, and 2,3,6,7-tetramethyl-9,10-di(1-naphthyl)anthracene.

Other examples of an organic compound that can be used are aromatic hydrocarbon compounds, such as 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, coronene, 4,4′-bis(2,2-diphenylvinyl)biphenyl (abbreviation: DPVBi), and 9,10-bis[4-(2,2-diphenylvinyl)phenyl]anthracene (abbreviation: DPVPA).

Further, examples of the electron acceptor are organic compounds, such as 7,7,8,8-tetracyano-2,3,5,6-tetrafluoroquinodimethane (abbreviation: F₄-TCNQ) and chloranil, transition metal oxides, and oxides of metals that belong to Groups 4 to 8 in the periodic table. Specific preferred examples include vanadium oxide, niobium oxide, tantalum oxide, chromium oxide, molybdenum oxide, tungsten oxide, manganese oxide, and rhenium oxide because their electron-acceptor properties are high. Among these, molybdenum oxide is especially preferable since it is stable in the air and its hygroscopic property is low and is easily treated.

The composite material may be formed using the above-described electron acceptor and the above-described high molecular compound, such as PVK, PVTPA, PTPDMA, or Poly-TPD, and used for the hole-injection layer 111.

The hole-transport layer 112 is a layer that contains a substance having a high hole-transport property. As the substance having a high hole-transport property, the following aromatic amine compounds can be used: NPB, TPD, BPAFLP, 4,4′-bis[N-(9,9-dimethylfluoren-2-yl)-N-phenylamino]biphenyl (abbreviation: DFLDPBi), 4,4′-bis[N-(spiro-9,9′-bifluoren-2-yl)-N-phenylamino]biphenyl (abbreviation: BSPB), and the like. The substances mentioned here are mainly substances that have a hole mobility of 10⁻⁶ cm²/Vs or more. Note that other than the above substances, any substance that has a property of transporting more holes than electrons may be used. Further, the layer including a substance having a high hole-transport property is not limited to a single layer, and may be a stack of two or more layers containing any of the above substances.

For the hole-transport layer 112, a carbazole derivative, such as CBP, CzPA, or PCzPA, or an anthracene derivative, such as t-BuDNA, DNA, or DPAnth, may be used.

For the hole-transport layer 112, a high molecular compound, such as PVK, PVTPA, PTPDMA, or Poly-TPD, can be used.

The light-emitting layer 113 is a layer that contains an organometallic complex described in Embodiment 1. The light-emitting layer 113 may be formed with a thin film containing an organometallic complex of one embodiment of the present invention. The light-emitting layer 113 may be a thin film in which the organometallic complex of one embodiment of the present invention is dispersed as a guest in a substance as a host which has higher triplet excitation energy than the organometallic complex of one embodiment of the present invention; thus, quenching of light emission from the organometallic complex caused depending on the concentration can be prevented. Note that the triplet excitation energy indicates an energy gap between a ground state and a triplet excited state.

The electron-transport layer 114 contains a substance having a high electron-transport property. Examples of the substance having a high electron-transport property include metal complexes such as Alq₃, tris(4-methyl-8-quinolinolato)aluminum (abbreviation: Almq₃), bis(10-hydroxybenzo[h]quinolinato)beryllium (abbreviation: BeBq₂), BAlq, Zn(BOX)₂, and bis[2-(2-benzothiazolyl)phenolato]zinc(II) (abbreviation: Zn(BTZ)₂). Alternatively, a heteroaromatic compound such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-biphenylyl)-4-phenyl-5-(4-tert-butylphenyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), or 4,4′-bis(5-methylbenzoxazol-2-yl)stilbene (abbreviation: BzOs) can be used. Further alternatively, a high molecular compound such as poly(2,5-pyridinediyl) (abbreviation: PPy), poly[(9,9-dihexylfluorene-2,7-diyl)-co-(pyridine-3,5-diyl)] (abbreviation: PF-Py) or poly[(9,9-dioctylfluorene-2,7-diyl)-co-(2,2′-bipyridine-6,6′-diyl)] (abbreviation: PF-BPy) can be used. The substances mentioned here are mainly ones that have an electron mobility of 10⁻⁶ cm²/V·s or higher. Note that any substance other than the above substances may be used for the electron-transport layer as long as the electron-transport property is higher than the hole-transport property.

Furthermore, the electron-transport layer is not limited to a single layer, and two or more layers made of the aforementioned substances may be stacked.

The electron-injection layer 115 contains a substance having a high electron-injection property. For the electron-injection layer 115, an alkali metal, an alkaline earth metal, or a compound thereof, such as lithium, cesium, calcium, lithium fluoride, cesium fluoride, calcium fluoride, or lithium oxide, can be used. Alternatively, a rare earth metal compound like erbium fluoride can be used. Further alternatively, the above-described substances for forming the electron-transport layer 114 can be used.

Alternatively, a composite material in which an organic compound and an electron donor (donor) are mixed may be used for the electron-injection layer 115. The composite material is superior in an electron-injection property and an electron-transport property, since electrons are generated in the organic compound by the electron donor. In this case, the organic compound is preferably a material excellent in transporting the generated electrons. Specifically, the above-described substances for forming the electron-transport layer 114 (e.g., a metal complex and a heteroaromatic compound) can be used, for example. As the electron donor, any substance which shows an electron-donating property with respect to the organic compound may be used. Preferable examples are an alkali metal, an alkaline earth metal, and a rare earth metal. Specifically, lithium, cesium, magnesium, calcium, erbium, and ytterbium can be given. Further, an alkali metal oxide and an alkaline earth metal oxide are preferable, and a lithium oxide, a calcium oxide, a barium oxide, and the like can be given. Alternatively, Lewis base such as magnesium oxide can be used. Further alternatively, an organic compound such as tetrathiafulvalene (abbreviation: TTF) can be used.

Note that each of the above-described hole-injection layer 111, hole-transport layer 112, light-emitting layer 113, electron-transport layer 114, and electron-injection layer 115 can be formed by a method such as an evaporation method (e.g., a vacuum evaporation method), an inkjet method, or a coating method.

For the second electrode 103 functioning as a cathode, any of metals, alloys, electrically conductive compounds, mixtures thereof, and the like with a low work function (specifically, a work function of 3.8 eV or lower) is preferably used. Specifically, in addition to elements that belong to Group 1 or 2 in the periodic table, that is, alkali metals such as lithium and cesium, alkaline earth metals such as magnesium, calcium, and strontium, and alloys thereof (e.g., Mg—Ag and Al—Li), rare earth metals such as europium and ytterbium, and alloys thereof, aluminum, silver, or the like can be used.

Note that, in the case where in the EL layer 102, a layer formed in contact with the second electrode 103 is formed using a composite material in which the organic compound and the electron donor (donor), which are described above, are mixed, a variety of conductive materials such as Al, Ag, ITO, and indium tin oxide containing silicon or silicon oxide can be used regardless of the work function.

In the formation of the second electrode 103, a vacuum evaporation method or a sputtering method can be used. Note that in the case of using a silver paste or the like, a coating method, an ink-jet method, or the like can be used.

In the above-described light-emitting element, current flows due to a potential difference generated between the first electrode 101 and the second electrode 103 and holes and electrons recombine in the EL layer 102, so that light is emitted. Then, the emitted light is extracted outside through one or both of the first electrode 101 and the second electrode 103. Therefore, one or both of the first electrode 101 and the second electrode 103 are electrodes having a property of transmitting visible light.

With the use of the light-emitting element described in this embodiment, a passive-matrix light-emitting device or an active matrix light-emitting device in which a transistor controls driving of the light-emitting element can be manufactured.

Note that there is no particular limitation on a structure of the transistor in the case of manufacturing the active matrix type light-emitting device. For example, a staggered transistor or an inverted staggered transistor can be used as appropriate. Further, a driver circuit formed over a substrate may be formed using both of an n-channel transistor and a p-channel transistor or only either an n-channel transistor or a p-channel transistor. Furthermore, there is no particular limitation on the crystallinity of a semiconductor, film used for the transistor. For example, an amorphous semiconductor film or a crystalline semiconductor film can be used. As a material of the semiconductor film, an oxide semiconductor can be used as well as an element such as silicon.

Note that in this embodiment, the organometallic complex used in the light-emitting layer 113 of the light-emitting element of one embodiment of the present invention emits light having a sharp peak with a narrow half width in the green emission wavelength. Thus, a light-emitting element having a high color rendering property can be realized.

The light-emitting element in this embodiment includes the organometallic complex of one embodiment of the present invention, a light-emitting element with high emission efficiency can be realized. In addition, a light-emitting device with low power consumption can be realized. Thus, a light-emitting element with high reliability can be realized.

Note that a structure described in this embodiment can be used in appropriate combination with any of the structures described in the other embodiments.

### Embodiment 4

The light-emitting element of one embodiment of the present invention may include a plurality of light-emitting layers. For example, by providing a plurality of light-emitting layers, light which is a combination of the light emitted from the plurality of layers can be obtained. Thus, white light emission can be obtained, for example. In this embodiment, a mode of a light-emitting element including a plurality of light-emitting layers is described with reference to FIG. 1B.

FIG. 1B illustrates a light-emitting element having the EL layer 102 between the first electrode 101 and the second electrode 103. The EL layer 102 includes a first light-emitting layer 213 and a second light-emitting layer 215, so that light emission that is a mixture of light emission from the first light-emitting layer 213 and light emission from the second light-emitting layer 215 can be obtained in the light-emitting element illustrated in FIG. 1B. A separation layer 214 is preferably formed between the first light-emitting layer 213 and the second light-emitting layer 215.

In this embodiment, a light-emitting element in which the first light-emitting layer 213 contains an organometallic compound that emits blue light and the second light-emitting layer 215 contains an organometallic complex of one embodiment of the present invention is described; however, one embodiment of the present invention is not limited thereto.

The organometallic complex of one embodiment of the present invention may be used in the first light-emitting layer 213, and another light-emitting substance may be applied to the second light-emitting layer 215.

The EL layer 102 may have three or more light-emitting layers.

When a voltage is applied so that the potential of the first electrode 101 is higher than the potential of the second electrode 103, a current flows between the first electrode 101 and the second electrode 103, and holes and electrons recombine in the first light-emitting layer 213, the second light-emitting layer 215, or the separation layer 214. Generated excitation energy is distributed to both the first light-emitting layer 213 and the second light-emitting layer 215 to excite a first light-emitting substance contained in the first light-emitting layer 213 and a second light-emitting substance contained in the second light-emitting layer 215. The excited first and second light-emitting substances emit light while returning to the ground state.

The first light-emitting layer 213 contains the first light-emitting substance typified by a fluorescent compound such as perylene, 2,5,8,11-tetra(tert-butyl)perylene (abbreviation: TBP), DPVBi, 4,4′-bis[2-(N-ethylcarbazol-3-yl)vinyl]biphenyl (abbreviation: BCzVBi), BAlq, or bis(2-methyl-8-quinolinolato)galliumchloride (abbreviation: Gamq₂Cl), or a phosphorescent compound such as bis{2-[3,5-bis(trifluoromethyl)phenyl]pyridinato-N,C^{2′}} iridium(III)picolinate (abbreviation: [Ir(CF₃ppy)₂(pic)]), bis[2-(4,6-difluorophenyepyridinato-N,C^{2′}]iridium(III)acetylacetonate (abbreviation: [FIr(acac)]), bis[2-(4,6-difluorophenyl)pyridinato-N,C^{2′}] iridium(III)picolinate (abbreviation: FIrpic), or bis[2-(4,6-difuluorophenyl)pyridinato-N,C^{2′}]iridium(III)tetra(1-pyrazolyl)borate (abbreviation: FIr6), from which light emission with a peak at 450 to 510 nm in an emission spectrum (i.e., blue light to blue green light) can be obtained.

In addition, when the first light-emitting substance is a fluorescent compound, the first light-emitting layer 213 preferably has a structure in which a substance that has larger singlet excitation energy than the first light-emitting substance is used as a first host material and the first light-emitting substance is dispersed as a guest material. Further, when the first light-emitting substance is a phosphorescent compound, the first light-emitting layer 213 preferably has a structure in which a substance that has larger triplet excitation energy than the first light-emitting substance is used as a first host material and the first light-emitting substance is dispersed as a guest material. As the first host material, DNA, t-BuDNA, or the like can be used in addition to the above-described NPB, CBP, TCTA, and the like. Note that the singlet excitation energy is an energy difference between a ground state and a singlet excited state.

The second light-emitting layer 215 contains the organometallic complex of one embodiment of the present invention and can emit green light. The second light-emitting layer 215 may have a structure similar to the light-emitting layer 113 described in Embodiment 3.

Specifically, the separation layer 214 can be formed using TPAQn, NPB, CBP, TCTA, Znpp₂, ZnBOX or the like described above. By thus providing the separation layer 214, a defect that emission intensity of one of the first light-emitting layer 213 and the second light-emitting layer 215 is stronger than that of the other can be prevented. Note that the separation layer 214 is not necessarily provided, and it may be provided as appropriate so that the ratio in emission intensity of the first light-emitting layer 213 and the second light-emitting layer 215 can be adjusted.

Other than the light-emitting layers, the hole-injection layer 111, the hole-transport layer 112, the electron-transport layer 114, and the electron-injection layer 115 are provided in the EL layer 102; as for structures of these layers, the structures of the respective layers described in Embodiment 3 can be applied. However, these layers are not necessarily provided and may be provided as appropriate according to element characteristics.

Note that a structure described in this embodiment can be used in appropriate combination with any of the structures described in the other embodiments.

### Embodiment 5

In this embodiment, as one embodiment of the present invention, a structure of a light-emitting element which includes a plurality of EL layers (hereinafter, referred to as a stacked-type element) is described with reference to FIG. 1C. This light-emitting element is a stacked-type light-emitting element including a plurality of EL layers (a first EL layer 700 and a second EL layer 701 in FIG. 1C) between a first electrode 101 and a second electrode 103. Note that, although the structure in which two EL layers are formed is described in this embodiment, a structure in which three or more EL layers are formed may be employed.

In this embodiment, the structures described in Embodiment 3 can be applied to the first electrode 101 and the second electrode 103.

In this embodiment, all or any of the plurality of EL layers may have the same structure as the EL layer described in Embodiment 3. In other words, the structures of the first EL layer 700 and the second EL layer 701 may be the same as or different from each other and can be the same as in Embodiment 3.

In FIG. 1C, a charge-generation layer 305 is provided between the first EL layer 700 and the second EL layer 701. The charge-generation layer 305 has a function of injecting electrons into one of the EL layers and injecting holes into the other of the EL layers when voltage is applied between the first electrode 101 and the second electrode 103. In this embodiment, when voltage is applied such that the potential of the first electrode 101 is higher than that of the second electrode 103, the charge-generation layer 305 injects electrons into the first EL layer 700 and injects holes into the second EL layer 701.

Note that the charge generation layer 305 preferably has a property of transmitting visible light in terms of light extraction efficiency. Further, the charge generation layer 305 functions even if it has lower conductivity than the first electrode 101 or the second electrode 103.

The charge generation layer 305 may have either a structure including an organic compound having a high hole-transport property and an electron acceptor (acceptor) or a structure including an organic compound having a high electron-transport property and an electron donor (donor). Alternatively, both of these structures may be stacked.

In the case of the structure in which an electron acceptor is added to an organic compound having a high hole-transport property, as the organic compound having a high hole-transport property, for example, an aromatic amine compound such as NPB, TPD, TDATA, MTDATA, or 4,4′-bis[N-(spiro-9,9′-bifluoren-2-yl)-N-phenylamino]biphenyl (abbreviation: BSPB), or the like can be used. The substances mentioned here are mainly ones that have a hole mobility of 10⁻⁶ cm²/V·s or higher. However, substances other than the above substances may be used as long as they are organic compounds in which a hole-transport property is higher than an electron-transport property.

Further, as the electron acceptor, 7,7,8,8-tetracyano-2,3,5,6-tetrafluoroquinodimethane (abbreviation: F₄-TCNQ), chloranil, and the like can be given. In addition, a transition metal oxide can be given. In addition, an oxide of metals that belong to Group 4 to Group 8 of the periodic table can be given. Specifically, vanadium oxide, niobium oxide, tantalum oxide, chromium oxide, molybdenum oxide, tungsten oxide, manganese oxide, and rhenium oxide are preferable since their electron-accepting property is high. Among these, molybdenum oxide is especially preferable since it is stable in the air, its hygroscopic property is low, and it is easily treated.

On the other hand, in the case of the structure in which an electron donor is added to an organic compound having a high electron-transport property, as the organic compound having a high electron-transport property, for example, a metal complex having a quinoline skeleton or a benzoquinoline skeleton, such as Alq, Almq₃, BeBq₂, or BAlq, or the like can be used. Alternatively, a metal complex having an oxazole-based ligand or a thiazole-based ligand, such as Zn(BOX)₂ or Zn(BTZ)₂ can be used. Further alternatively, other than such a metal complex, PBD, OXD-7, TAZ, BPhen, BCP, or the like can be used. The substances mentioned here are mainly ones that have an electron mobility of 10⁻⁶ cm²/V·s or higher. Note that any substance other than the above substances may be used as long as the electron-transport property is higher than the hole-transport property.

Further, as the electron donor, an alkali metal, an alkaline earth metal, a rare earth metal, a metal belonging to Group 13 of the periodic table, or an oxide or carbonate thereof can be used. Specifically, lithium, cesium, magnesium, calcium, ytterbium, indium, lithium oxide, cesium carbonate, or the like is preferably used. Alternatively, an organic compound such as tetrathianaphthacene may be used as the electron donor.

Note that forming the charge-generation layer 305 by using any of the above materials can suppress an increase in drive voltage caused by the stack of the EL layers.

Although the light-emitting element having two EL layers is described in this embodiment, the present invention can be similarly applied to a light-emitting element in which three or more EL layers are stacked. As in the case of the light-emitting element described in this embodiment, by arranging a plurality of EL layers to be partitioned from each other with charge-generation layers between a pair of electrodes, light emission in a high luminance region can be achieved with current density kept low. Since current density can be kept low, the element can have a long lifetime. When the light-emitting element is applied for illumination, voltage drop due to resistance of an electrode material can be reduced, thereby achieving homogeneous light emission in a large area. Moreover, a light-emitting device of low power consumption, which can be driven at a low voltage, can be achieved.

By forming EL layers to emit light of different colors from each other, a light-emitting element as a whole can provide light emission of a desired color. For example, by forming a light-emitting element having two EL layers such that the emission color of the first EL layer and the emission color of the second EL layer are complementary colors, the light-emitting element can provide white light emission as a whole. Note that the word “complementary” means color relationship in which an achromatic color is obtained when colors are mixed. That is, white light emission can be obtained by mixture of light from substances, of which the light emission colors are complementary colors.

The same can be applied to a light-emitting element having three EL layers. For example, the light-emitting element as a whole can provide white light emission when the emission color of a first EL layer is red, the emission color of a second EL layer is green, and the emission color of a third EL layer is blue.

Note that the structure described in this embodiment can be used in combination with any of the structures described in the other embodiments, as appropriate.

### Embodiment 6

In this embodiment, a passive matrix light-emitting device and an active matrix light-emitting device in each of which a light-emitting element of one embodiment of the present invention is used are described.

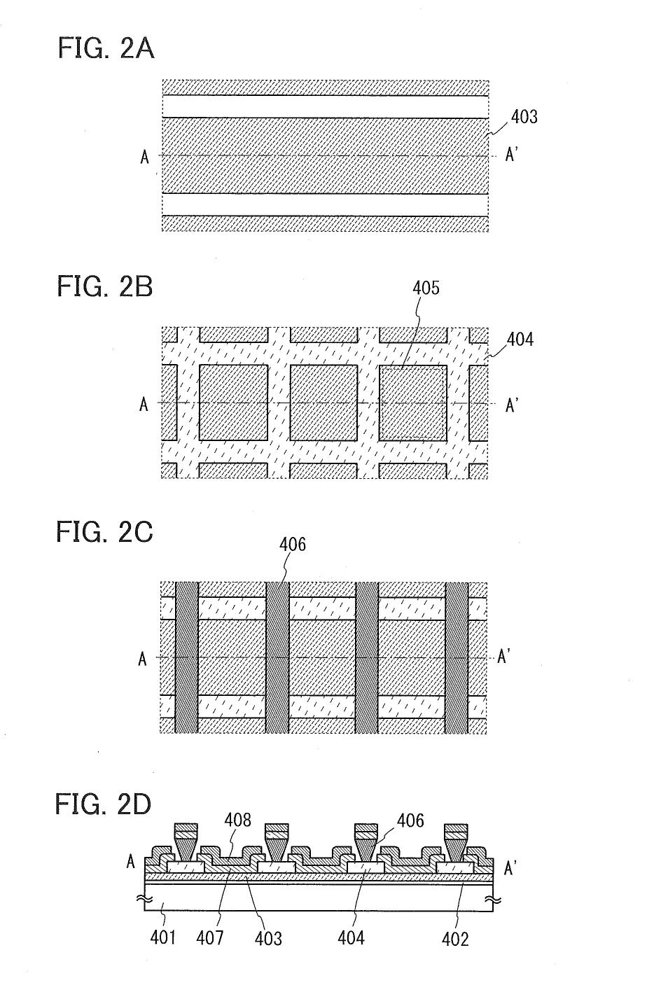

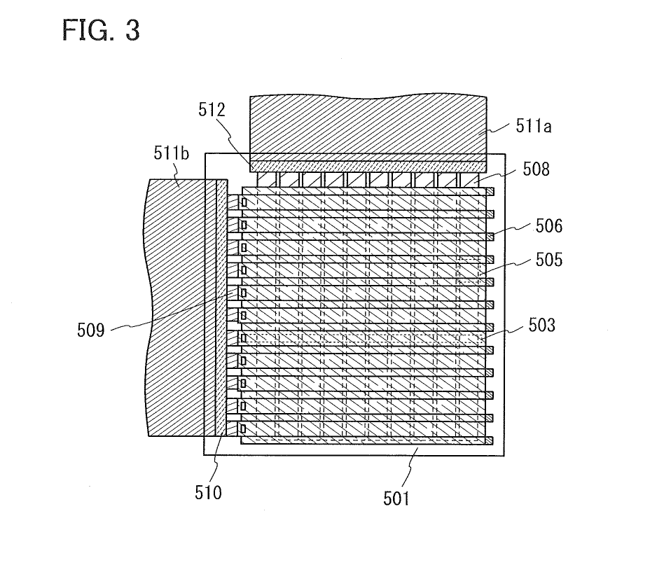

FIGS. 2A to 2D and FIG. 3 illustrate an example of the passive matrix light-emitting device.

In a passive matrix (also called simple matrix) light-emitting device, a plurality of anodes arranged in stripes (in stripe form) are provided to be perpendicular to a plurality of cathodes arranged in stripes. A light-emitting layer is interposed at each intersection. Therefore, a pixel at an intersection of an anode selected (to which a voltage is applied) and a cathode selected emits light.

FIGS. 2A to 2C are top views of a pixel portion before sealing. FIG. 2D is a cross-sectional view taken along the dashed-dotted line A-A′ in FIGS. 2A to 2C.

An insulating layer 402 is formed as a base insulating layer over a substrate 401. Note that the insulating layer 402 is not necessarily formed if the base insulating layer is not needed. A plurality of first electrodes 403 are arranged in stripes at regular intervals over the insulating layer 402 (see FIG. 2A).

In addition, partition 404 having openings corresponding to the pixels is provided over the first electrodes 403. The partition 404 having the openings is formed using an insulating material, such as a photosensitive or nonphotosensitive organic material (polyimide, acrylic, polyamide, polyimide amide, resist, or benzocyclobutene) or a SOG film (e.g., a SiOₓ film containing an alkyl group). Note that openings 405 corresponding to the pixels serve as light-emitting regions (FIG. 2B).

Over the partition 404 having the openings, a plurality of reversely tapered partitions 406 which are parallel to each other are provided to intersect with the first electrodes 403 (FIG. 2C). The reversely tapered partitions 406 are formed in the following manner: according to a photolithography method, a positive photosensitive resin, an unexposed portion of which serves as a pattern, is used and the amount of exposed light or the length of development time is adjusted so that a lower portion of the pattern is etched more.

After the reversely tapered partitions 406 are formed as illustrated in FIG. 2C, an EL layer 407 and a second electrode 408 are sequentially formed as illustrated in FIG. 2D. The total thickness of the partition 404 having the openings and the reversely tapered partition 406 is set to be larger than the total thickness of the EL layer 407 and the second electrode 408; thus, as illustrated in FIG. 2D, EL layers 407 and second electrodes 408 which are separated for plural regions are formed. Note that the plurality of separated regions are electrically isolated from one another.

The second electrodes 408 are electrodes in stripe form that are parallel to each other and extend along a direction intersecting with the first electrodes 403. Note that parts of a layer for forming the EL layers 407 and parts of a conductive layer for forming the second electrodes 408 are also formed over the reversely tapered partitions 406; however, these parts are separated from the EL layers 407 and the second electrodes 408.

Note that there is no particular limitation on the first electrode 403 and the second electrode 408 in this embodiment as long as one of them is an anode and the other is a cathode. Note that a stacked structure in which the EL′ layer 407 is included may be adjusted as appropriate in accordance with the polarity of the electrode.

Further, if necessary, a sealing material such as a sealing can or a glass substrate may be attached to the substrate 401 for sealing with an adhesive such as a sealing material, so that the light-emitting element is placed in the sealed space. Thereby, deterioration of the light-emitting element can be prevented. The sealed space may be filled with filler or a dry inert gas. Furthermore, a desiccant or the like may be put between the substrate and the sealing material in order to prevent deterioration of the light-emitting element due to moisture or the like. The desiccant removes a minute amount of moisture, thereby achieving sufficient desiccation. The desiccant may be a substance which adsorbs moisture by chemical adsorption such as an oxide of an alkaline earth metal such as calcium oxide or barium oxide. Additionally, a substance which adsorbs moisture by physical adsorption such as zeolite or silica gel may be used as well, as a desiccant.

FIG. 3 is a top view of the passive-matrix light-emitting device illustrated in FIGS. 2A to 2D that is provided with a flexible printed circuit (an FPC) and the like.

In FIG. 3, in a pixel portion forming an image display, scanning lines and data lines are arranged to intersect with each other so that the scanning lines and the data lines are perpendicular to each other.

The first electrodes 403 in FIGS. 2A to 2D correspond to scanning lines 503 in FIG. 3; the second electrodes 408 in FIGS. 2A to 2D correspond to data lines 508 in FIG. 3; and the reversely tapered partitions 406 correspond to partitions 506. The EL layer 407 in FIGS. 2A to 2D is interposed between the data lines 508 and the scan lines 503, and an intersection indicated as a region 505 corresponds to one pixel.

Note that the scan lines 503 are electrically connected at their ends to connection wirings 509, and the connection wirings 509 are connected to an FPC 511b through an input terminal 510. In addition, the data lines 508 are connected to an FPC 511a through an input terminal 512.

If necessary, an optical film such a polarizing plate, a circularly polarizing plate (including an elliptically polarizing plate), a retardation plate (a quarter-wave plate or a half-wave plate), and a color filter may be provided as appropriate on a surface through which light is emitted. Further, the polarizing plate or the circularly polarizing plate may be provided with an anti-reflection film. For example, anti-glare treatment by which reflected light can be diffused by projections and depressions on the surface so as to reduce the glare can be performed.

Although FIG. 3 illustrates the example in which a driver circuit is not provided over a substrate 501, an IC chip including a driver circuit may be mounted on the substrate 501.

When the IC chip is mounted, a data line side IC and a scan line side IC, in each of which a driver circuit for transmitting a signal to a pixel portion is formed, are mounted on the periphery of the pixel portion (outside the pixel portion) by a COG method. The mounting may be performed using a TCP or a wire bonding method other than the COG method. The TCP is a TAB tape mounted with the IC, and the TAB tape is connected to a wiring over an element formation substrate to mount the IC. The ICs on the data line side and the scan line side may be formed using a silicon substrate, or may be obtained by formation of a driver circuit with an FET over a glass substrate, a quartz substrate, or a plastic substrate.

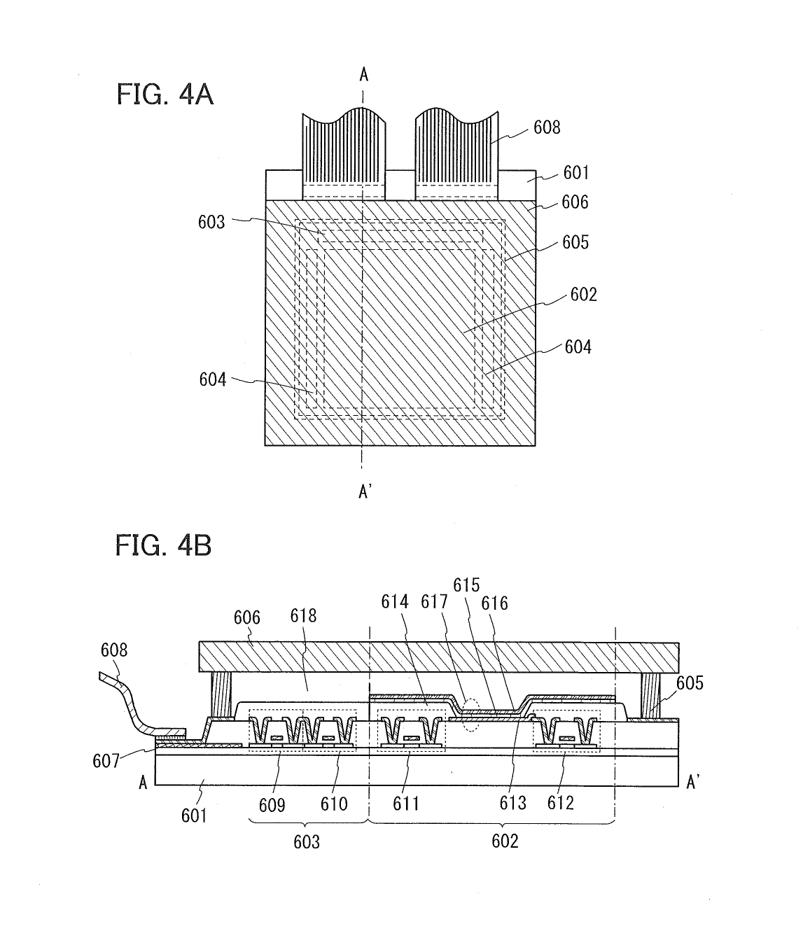

Next, an example of the active-matrix light-emitting device is described with reference to FIGS. 4A and 4B. FIG. 4A is a top view illustrating a light-emitting device and FIG. 4B is a cross-sectional view taken along the dashed-dotted line A-A′ in FIG. 4A. The active matrix light-emitting device of this embodiment includes a pixel portion 602 provided over an element substrate 601, a driver circuit portion (a source side driver circuit) 603, and driver circuit portions (gate side driver circuits) 604. The pixel portion 602, the driver circuit portion 603, and the driver circuit portions 604 are sealed between the element substrate 601 and a sealing substrate 606 with a sealing material 605.

In addition, over the element substrate 601, a lead wiring 607 for connecting an external input terminal, through which a signal (e.g., a video signal, a clock signal, a start signal, a reset signal, or the like) or an electric potential is transmitted to the driver circuit portion 603 and the driver circuit portions 604, is provided. Here, an example is described in which a flexible printed circuit (FPC) 608 is provided as the external input terminal. Although only the FPC is illustrated here, a printed wiring board (PWB) may be attached to the FPC. The light-emitting device in the present specification includes, in its category, not only the light-emitting device itself but also the light-emitting device provided with the FPC or the PWB.

Next, a cross-sectional structure is described with reference to FIG. 4B. The driver circuit portion and the pixel portion are formed over the element substrate 601, and in FIG. 4B, the driver circuit portion 603 that is a source side driver circuit and the pixel portion 602 are illustrated.

An example is illustrated in which a CMOS circuit which is a combination of an n-channel FET 609 and a p-channel FET 610 is formed as the driver circuit portion 603. Note that the driver circuit portion may be formed using various CMOS circuits, PMOS circuits, or NMOS circuits. Although a driver integrated type in which the driver circuit is formed over the substrate is described in this embodiment, the driver circuit may not necessarily be formed over the substrate, and the driver circuit can be formed outside, not over the substrate.

The pixel portion 602 is formed of a plurality of pixels each of which includes a switching FET 611, a current control FET 612, and an anode 613 which is electrically connected to a wiring (a source electrode or a drain electrode) of the current control FET 612. Note that an insulator 614 is formed to cover end portions of the anode 613. In this embodiment, the insulator 614 is formed using a positive photosensitive acrylic resin.

In addition, in order to obtain favorable coverage by a film which is to be stacked over the insulator 614, the insulator 614 is preferably formed so as to have a curved surface with curvature at an upper edge portion or a lower edge portion. For example, in the case of using a positive photosensitive acrylic resin as a material for the insulator 614, the insulator 614 is preferably formed so as to have a curved surface with a curvature radius (greater than or equal to 0.2 μm and less than or equal to 3 μm) at the upper edge portion. As a material of the insulator 614, an organic compound such as a negative photosensitive resin or a positive photosensitive resin, or an inorganic compound such as silicon oxide or silicon oxynitride can be used.

An EL layer 615 and a cathode 616 are stacked over the anode 613. Note that when an ITO film is used as the anode 613, and a stacked film of a titanium nitride film and a film containing aluminum as its main component or a stacked film of a titanium nitride film, a film containing aluminum as its main component, and a titanium nitride film is used as the wiring of the current controlling FET 612 which is connected to the anode 613, resistance of the wiring is low and favorable ohmic contact with the ITO film can be obtained. Note that, although not illustrated in FIGS. 4A and 4B, the cathode 616 is electrically connected to the FPC 608 which is an external input terminal.

Note that in the EL layer 615, at least a light-emitting layer is provided, and in addition to the light-emitting layer, a hole-injection layer, a hole-transport layer, an electron-transport layer, or an electron-injection layer is provided as appropriate. A light-emitting element 617 is formed of a stacked structure of the anode 613, the EL layer 615, and the cathode 616.

Although the cross-sectional view of FIG. 4B illustrates only one light-emitting element 617, a plurality of light-emitting elements are arranged in matrix in the pixel portion 602. Light-emitting elements which provide three kinds of emissions (R, G, and B) are selectively formed in the pixel portion 602, whereby a light-emitting device capable of full color display can be formed. Alternatively, a light-emitting device which is capable of full color display may be manufactured by a combination with color filters.

Further, the sealing substrate 606 is attached to the element substrate 601 with the sealing material 605, so that the light-emitting element 617 is provided in a space 618 enclosed by the element substrate 601, the sealing substrate 606, and the sealing material 605. The space 618 may be filled with an inert gas (such as nitrogen or argon), or the sealing material 605.

An epoxy based resin is preferably used for the sealing material 605. A material used for them is desirably a material which does not transmit moisture or oxygen as much as possible. As a material used for the sealing substrate 606, a plastic substrate formed of fiber-reinforced plastics (FRP), polyvinyl fluoride (PVF), polyester, acrylic, or the like can be used other than a glass substrate or a quartz substrate.

As described above, an active matrix light-emitting device can be obtained.

Note that in this specification and the like, a transistor or a light-emitting element can be formed using any of a variety of substrates, for example. The type of a substrate is not limited to a certain type. As the substrate, a semiconductor substrate (e.g., a single crystal substrate or a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, paper including a fibrous material, a base material film, or the like can be used, for example. As an example of a glass substrate, a barium borosilicate glass substrate, an aluminoborosilicate glass substrate, a soda lime glass substrate, or the like can be given. Examples of the flexible substrate, the attachment film, the base film, and the like are substrates of plastics typified by polyethylene terephthalate (PET), polyethylene naphthalate (PEN), polyether sulfone (PES), and polytetrafluoroethylene (PTFE). Another example is a synthetic resin such as acrylic. Alternatively, polypropylene, polyester, polyvinyl fluoride, polyvinyl chloride, or the like can be used. Alternatively, polyamide, polyimide, aramid, epoxy, an inorganic vapor deposition film, paper, or the like can be used. Specifically, the use of semiconductor substrates, single crystal substrates, SOI substrates, or the like enables the manufacture of small-sized transistors with a small variation in characteristics, size, shape, or the like and with high current supply capability. A circuit using such transistors achieves lower power consumption of the circuit or higher integration of the circuit.

Alternatively, a flexible substrate may be used as the substrate, and the transistor or the light-emitting element may be provided directly on the flexible substrate. Still alternatively, a separation layer may be provided between the substrate and the transistor or the light-emitting element. The separation layer can be used when part Or the whole of a semiconductor device formed over the separation layer is separated from the substrate and transferred onto another substrate. In such a case, the transistor or the light-emitting element can be transferred to a substrate having low heat resistance or a flexible substrate. For the separation layer, a stack including inorganic films such as a tungsten film and a silicon oxide film, or an organic resin film of polyimide or the like formed over a substrate can be used, for example.

In other words, a transistor or a light-emitting element may be formed using one substrate, and then transferred to another substrate. Examples of a substrate to which a transistor or a light-emitting element is transferred include, in addition to the above-described substrates over which a transistor or a light-emitting element can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupra, rayon, or regenerated polyester), or the like), a leather substrate, and a rubber substrate. When such a substrate is used, a transistor with excellent characteristics and a transistor with low power consumption can be formed, a device with high durability or high heat resistance can be provided, or a reduction in weight or thickness can be achieved.

Note that a structure described in this embodiment can be used in appropriate combination with any of the structures described in the other embodiments.

### Embodiment 7

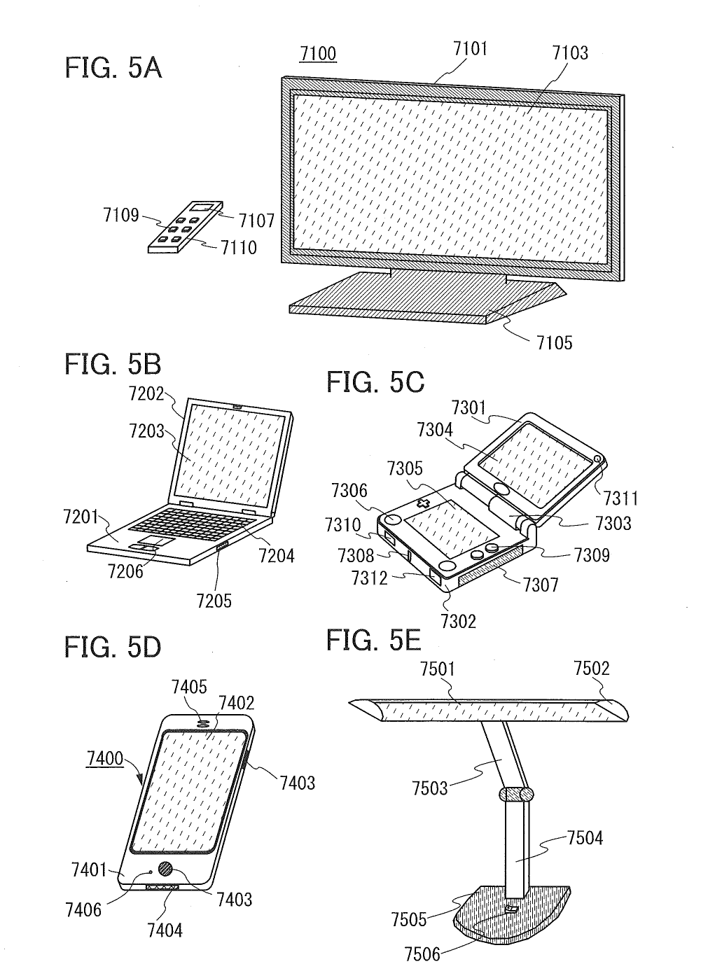

In this embodiment, examples of a variety of electronic devices and lighting devices that are completed with a light-emitting device of one embodiment of the present invention are described with reference to FIGS. 5A to 5E, FIGS. 6A and 6B, and FIG. 7.

Examples of the electronic devices are a television device to which the light-emitting device is applied (also referred to as television or television receiver), a monitor of a computer or the like, a camera such as a digital camera or a digital video camera, a digital photo frame, a mobile phone (also referred to as cellular phone or cellular phone device), a portable game machine, a portable information terminal, an audio reproducing device, and a large-sized game machine such as a pachinko machine.

An electronic device or a lighting device that has a light-emitting portion with a curved surface can be obtained with the use of the light-emitting element of one embodiment of the present invention which is manufactured over a substrate having flexibility.

In addition, an electronic device or a lighting device that has a see-through light-emitting portion can be obtained with the use of the light-emitting element of one embodiment of the present invention in which a pair of electrodes are formed using a material having a property of transmitting visible light.

Further, a light-emitting device to which one embodiment of the present invention is applied can also be applied to lighting for motor vehicles, examples of which are lighting for a dashboard, a windshield, a ceiling, and the like.

Specific examples of these electronic devices and lighting devices are illustrated in FIGS. 5A to 5E, FIGS. 6A and 6B, and FIG. 7.

FIG. 5A illustrates an example of a television device. In a television device 7100, a display portion 7103 is incorporated in a housing 7101. Images can be displayed by the display portion 7103, and the light-emitting device can be used for the display portion 7103. In addition, here, the housing 7101 is supported by a stand 7105.

The television device 7100 can be operated by an operation switch of the housing 7101 or a separate remote controller 7110. With operation keys 7109 of the remote controller 7110, channels and volume can be controlled and images displayed on the display portion 7103 can be controlled. Furthermore, the remote controller 7110 may be provided with a display portion 7107 for displaying data output from the remote controller 7110.

Note that the television device 7100 is provided with a receiver, a modem, and the like. With the receiver, a general television broadcast can be received. Furthermore, when the television device 7100 is connected to a communication network by wired or wireless connection via the modem, one-way (from a transmitter to a receiver) or two-way (between a transmitter and a receiver, between receivers, or the like) data communication can be performed.

FIG. 5B illustrates a computer, which includes a main body 7201, a housing 7202, a display portion 7203, a keyboard 7204, an external connection port 7205, a pointing device 7206, and the like. This computer is manufactured by using a light-emitting device for the display portion 7203.

FIG. 5C illustrates a portable game machine having two housings, a housing 7301 and a housing 7302, which are connected with a joint portion 7303 so that the portable game machine can be opened or folded. A display portion 7304 is incorporated in the housing 7301 and a display portion 7305 is incorporated in the housing 7302. In addition, the portable game machine illustrated in FIG. 5C includes a speaker portion 7306, a recording medium insertion portion 7307, an LED lamp 7308, an input unit (an operation key 7309, a connection terminal 7310, a sensor 7311 (sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), or a microphone 7312), and the like. It is needless to say that the structure of the portable game machine is not limited to the above as long as a light-emitting device is used for at least either the display portion 7304 or the display portion 7305, or both, and may include other accessories as appropriate. The portable game machine illustrated in FIG. 5C has a function of reading a program or data stored in a recording medium to display it in the display portion, and a function of sharing information with another portable game machine by wireless communication. Note that the functions of the portable game machine illustrated in FIG. 5C are not limited to these functions, and the portable amusement machine can have various functions.

FIG. 5D illustrates an example of a cellular phone. A cellular phone 7400 is provided with a display portion 7402 incorporated in a housing 7401, operation buttons 7403, an external connection port 7404, a speaker 7405, a microphone 7406, and the like. Note that the cellular phone 7400 is manufactured using a light-emitting device for the display portion 7402.

When the display portion 7402 of the cellular phone 7400 illustrated in FIG. 5D is touched with a finger or the like, data can be input into the cellular phone 7400. Further, operations such as making a call and creating e-mail can be performed by touch on the display portion 7402 with a finger or the like.

There are mainly three screen modes of the display portion 7402. The first mode is a display mode mainly for displaying images. The second mode is an input mode mainly for inputting data such as text. The third mode is a display-and-input mode in which two modes of the display mode and the input mode are combined.

For example, in the case of making a call or creating e-mail, a text input mode mainly for inputting text is selected for the display portion 7402 so that text displayed on a screen can be inputted. In this case, it is preferable to display a keyboard or number buttons on almost the entire screen of the display portion 7402.

When a detection device including a sensor for detecting inclination, such as a gyroscope or an acceleration sensor, is provided inside the cellular phone 7400, display on the screen of the display portion 7402 can be automatically changed by determining the orientation of the cellular phone 7400 (whether the cellular phone is placed horizontally or vertically for a landscape mode or a portrait mode).

The screen modes are switched by touching the display portion 7402 or operating the operation buttons 7403 of the housing 7401. Alternatively, the screen modes can be switched depending on kinds of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed within a specified period while a signal detected by an optical sensor in the display portion 7402 is detected, the screen mode may be controlled so as to be switched from the input mode to the display mode.

The display portion 7402 may also function as an image sensor. For example, an image of a palm print, a fingerprint, or the like is taken by touch on the display portion 7402 with the palm or the finger, whereby personal authentication can be performed. Further, by providing a backlight or a sensing light source which emits near-infrared light in the display portion, an image of a finger vein, a palm vein, or the like can be taken.

As described above, by applying the light-emitting device of one embodiment of the present invention, a display portion of an electronic device can realize high emission efficiency. By applying one embodiment of the present invention, an electronic device with high reliability can be provided. By applying one embodiment of the present invention, an electronic device with low power consumption can be provided.

FIG. 5E illustrates a desk lamp including a lighting portion 7501, a shade 7502, an adjustable arm 7503, a support 7504, a base 7505, and a power supply switch 7506. The desk lamp is manufactured using a light-emitting device for the lighting portion 7501. Note that a lamp includes a ceiling light, a wall light, and the like in its category.

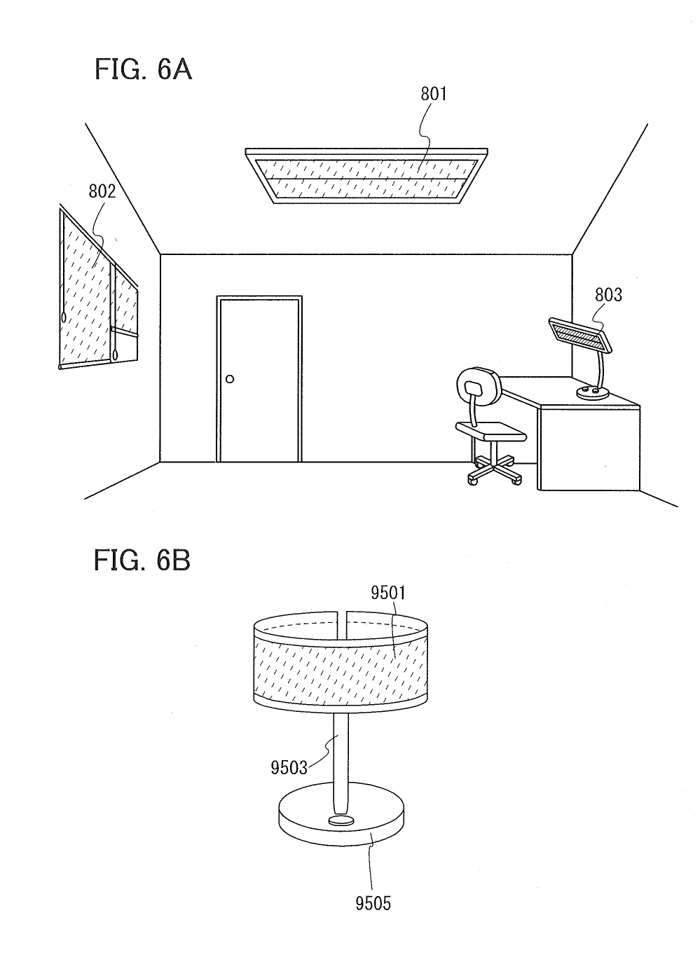

FIG. 6A illustrates an example in which a light-emitting device is used for an interior lighting device 801. Since the light-emitting device can be enlarged, the light-emitting device can be used as a large-area lighting device. Alternatively, the light-emitting device can be used as a roll-type lighting device 802. As illustrated in FIG. 6A, a desk lamp 803 described with reference to FIG. 5E may be used together in a room provided with the interior lighting device 801.

FIG. 6B illustrates an example of another lighting device. A desk lamp illustrated in FIG. 6B includes a lighting portion 9501, a support 9503, a support base 9505, and the like. The lighting portion 9501 contains any of the organometallic complexes each of which is one embodiment of the present invention. By thus fabricating a light-emitting device of one embodiment of the present invention over a flexible substrate, a lighting device having a curved surface or having a flexible lighting portion can be provided. The use of a flexible light-emitting device for a lighting device as described above not only improves the degree of freedom in design of the lighting device but also enables the lighting device to be mounted onto a portion having a curved surface, such as the ceiling or a dashboard of a car.

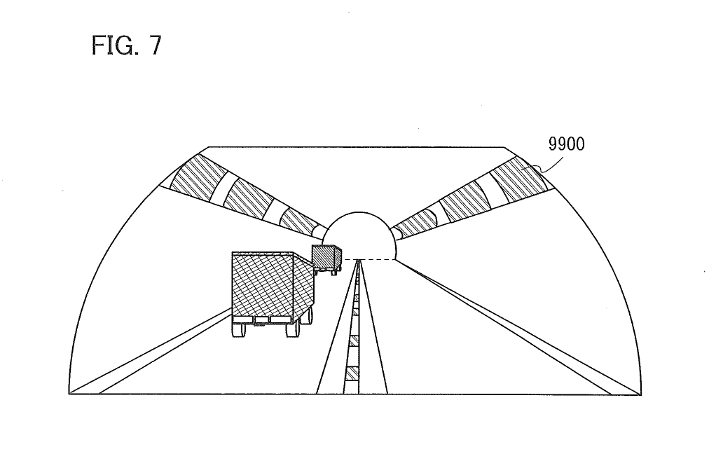

FIG. 7 illustrates an example of another lighting device. As described above, a lighting device having a curved surface can be fabricated by applying one embodiment of the present invention. In addition, since the organometallic complex of one embodiment of the present invention emits yellow to orange light, a yellow lighting device or an orange lighting device can be provided. For example, one embodiment of the present invention can be applied to a lighting device 9900 in a tunnel illustrated in FIG. 7. By applying one embodiment of the present invention, a lighting device with high emission efficiency and high energy efficiency can be realized. In addition, since yellow to orange light emission has a high luminosity factor, accidents can be reduced. Further, since the lighting device to which one embodiment of the present invention is applied is a plane light source, the directivity can be prevented from being too strong, so that causes of accidents can be reduced.

Alternatively, the above-described yellow lighting device can be applied to a yellow room or the like. By using a lighting device to which one embodiment of the present invention is applied for lighting in a yellow room, a shade is unlikely to be generated and favorable environment for working can be provided.

As described above, by applying the light-emitting device of one embodiment of the present invention, a lighting device can realize high emission efficiency. By applying one embodiment of the present invention, a lighting device with high reliability can be provided. By applying one embodiment of the present invention, a lighting device with low power consumption can be provided.

As described above, electronic devices or lighting devices can be obtained by application of the light-emitting device. The light-emitting device has an extremely wide application range, and can be applied to electronic devices in a variety of fields.

Note that a structure described in this embodiment can be used in appropriate combination with any of the structures described in the other embodiments.

### Embodiment 8

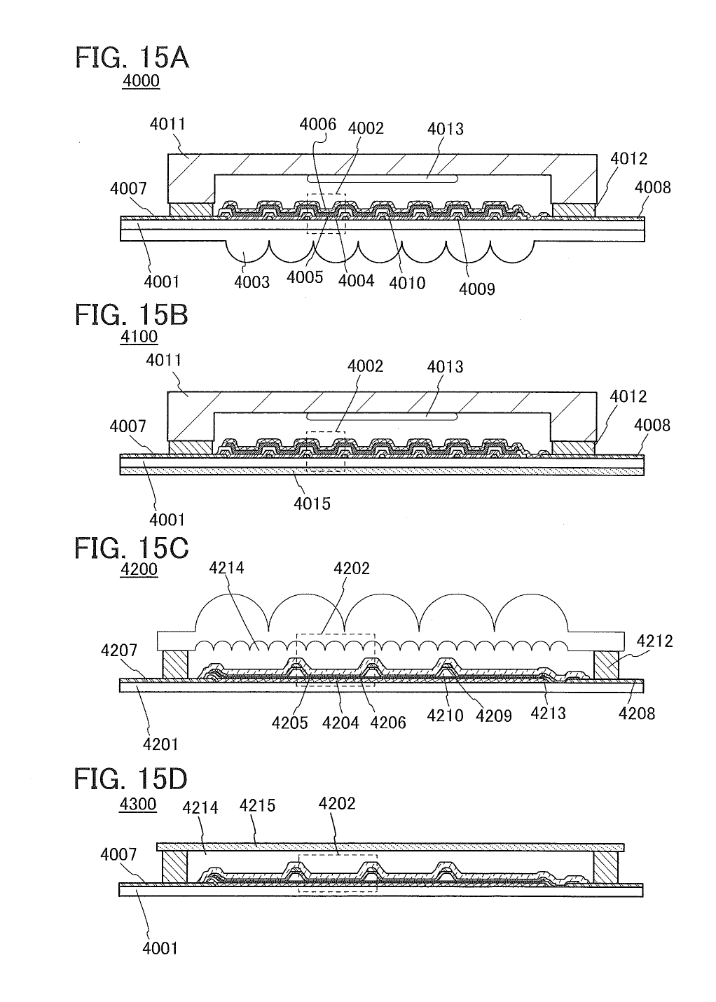

In this embodiment, a structure of a lighting device fabricated with the light-emitting element of one embodiment of the present invention will be described with reference to FIGS. 15A to 15D.

FIGS. 15A to 15D illustrate examples of cross-sectional views of the lighting devices. FIGS. 15A and 15B illustrate bottom-emission lighting devices in which light is extracted from the substrate side, and FIGS. 15C and 15D illustrate top-emission lighting devices in which light is extracted from the sealing substrate side.

A lighting device 4000 illustrated in FIG. 15A includes a light-emitting element 4002 over a substrate 4001. In addition, the lighting device 4000 includes a substrate 4003 with unevenness on an outer surface of the substrate 4001. The light-emitting element 4002 includes a first electrode 4004, an EL layer 4005, and a second electrode 4006.

The first electrode 4004 is electrically connected to an electrode 4007. The second electrode 4006 is electrically connected to an electrode 4008. An auxiliary wiring 4009 electrically connected to the first electrode 4004 may be provided. Note that an insulating layer 4010 is provided over the auxiliary wiring 4009.

The substrate 4001 and a sealing substrate 4011 are bonded to each other by a sealant 4012. A desiccant 4013 is preferably provided between the sealing substrate 4011 and the light-emitting element 4002. The substrate 4003 has the unevenness illustrated in FIG. 15A, whereby the extraction efficiency of light emitted from the light-emitting element 4002 can be increased.

Instead of the substrate 4003, a diffusion plate 4015 may be provided on the outside of a substrate 4001 as in a lighting device 4100 illustrated in FIG. 15B.

A lighting device 4200 illustrated in FIG. 15C includes a light-emitting element 4202 over a substrate 4201. The light-emitting element 4202 includes a first electrode 4204, an EL layer 4205, and a second electrode 4206.

The first electrode 4204 is electrically connected to an electrode 4207. The second electrode 4206 is electrically connected to an electrode 4208. An auxiliary wiring 4209 electrically connected to the second electrode 4206 may be provided. An insulating layer 4210 may be provided under the auxiliary wiring 4209.

The substrate 4201 and a sealing substrate 4211 with unevenness are bonded to each other by a sealant 4212. A barrier film 4213 and a planarization film 4214 may be provided between the sealing substrate 4211 and the light-emitting element 4202. The sealing substrate 4211 has the unevenness illustrated in FIG. 15C, whereby the extraction efficiency of light emitted from the light-emitting element 4202 can be increased.

Instead of the sealing substrate 4211, a diffusion plate 4215 may be provided over the light-emitting element 4202 as in a lighting device 4300 illustrated in FIG. 15D.

Note that the EL layers 4005 and 4205 in this embodiment can include the organometallic complex of one embodiment of the present invention. In that case, a lighting device with low power consumption can be provided.

Note that a structure described in this embodiment can be used in appropriate combination with any of the structures described in the other embodiments.

### Embodiment 9

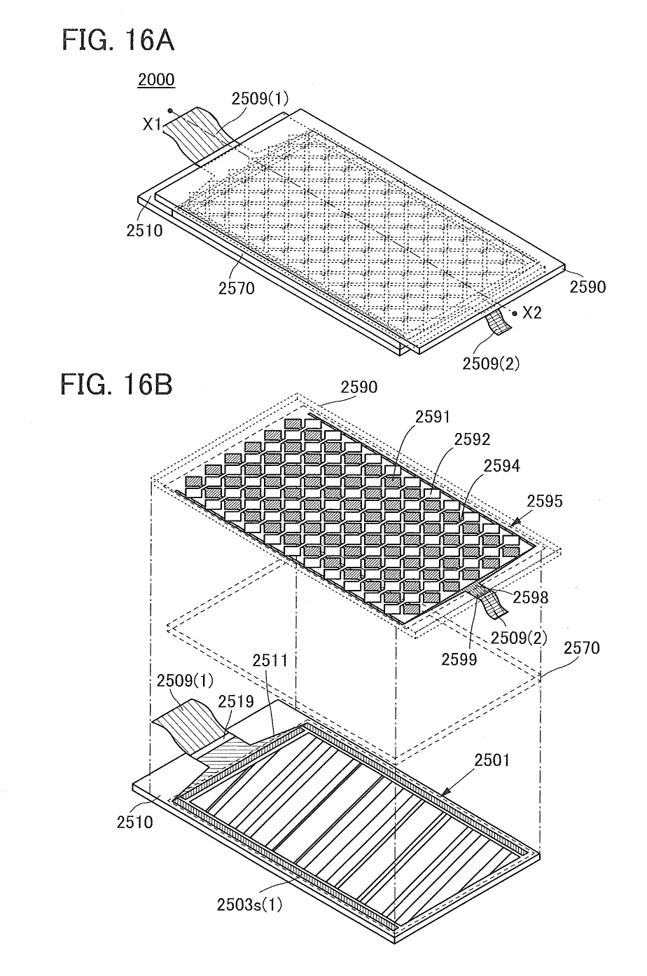

In this embodiment, touch panels including a light-emitting element of one embodiment of the present invention or a light-emitting device of one embodiment of the present invention will be described with reference to FIGS. 16A and 16B, FIGS. 17A and 17B, FIGS. 18A and 18B, FIGS. 19A and 19B, and FIG. 20.

FIGS. 16A and 16B are perspective views of a touch panel 2000. Note that FIGS. 16A and 16B illustrate typical components of the touch panel 2000 for simplicity.

The touch panel 2000 includes a display portion 2501 and a touch sensor 2595 (see FIG. 16B). Furthermore, the touch panel 2000 includes a substrate 2510, a substrate 2570, and a substrate 2590. Note that the substrate 2510, the substrate 2570, and the substrate 2590 each have flexibility.

The display portion 2501 includes a plurality of pixels over the substrate 2510, and a plurality of wirings 2511 through which signals are supplied to the pixels. The plurality of wirings 2511 are led to a peripheral portion of the substrate 2510, and part of the plurality of wirings 2511 forms a terminal 2519. The terminal 2519 is electrically connected to an FPC 2509(1).

The substrate 2590 includes the touch sensor 2595 and a plurality of wirings 2598 electrically connected to the touch sensor 2595. The plurality of wirings 2598 are led to a peripheral portion of the substrate 2590, and part of the plurality of wirings 2598 forms a terminal 2599. The terminal 2599 is electrically connected to an FPC 2509(2). Note that in FIG. 16B, electrodes, wirings, and the like of the touch sensor 2595 provided on the back side of the substrate 2590 (the side facing the substrate 2510) are indicated by solid lines for clarity.

As the touch sensor 2595, a capacitive touch sensor can be used, for example. Examples of the capacitive touch sensor are a surface capacitive touch sensor and a projected capacitive touch sensor.

Examples of the projected capacitive touch sensor are a self capacitive touch sensor and a mutual capacitive touch sensor, which differ mainly in the driving method. The use of a mutual capacitive touch sensor is preferable because multiple points can be sensed simultaneously.

First, an example of using a projected capacitive touch sensor will be described below with reference to FIG. 16B. Note that in the case of a projected capacitive touch sensor, a variety of sensors that can sense the closeness or the contact of a sensing target such as a finger can be used.

The projected capacitive touch sensor 2595 includes electrodes 2591 and electrodes 2592. The electrodes 2591 are electrically connected to any of the plurality of wirings 2598, and the electrodes 2592 are electrically connected to any of the other wirings 2598. The electrodes 2592 each have a shape of a plurality of quadrangles arranged in one direction with one corner of a quadrangle connected to one corner of another quadrangle with a wiring 2594 in one direction as illustrated in FIGS. 16A and 16B. In the same manner, the electrodes 2591 each have a shape of a plurality of quadrangles arranged with one corner of a quadrangle connected to one corner of another quadrangle; however, the direction in which the electrodes 2591 are connected is a direction crossing the direction in which the electrodes 2592 are connected. Note that the direction in which the electrodes 2591 are connected and the direction in which the electrodes 2592 are connected are not necessarily perpendicular to each other, and the electrodes 2591 may be arranged to intersect with the electrodes 2592 at an angle greater than 0° and less than 90°.

The intersecting area of the wiring 2594 and one of the electrodes 2592 is preferably as small as possible. Such a structure allows a reduction in the area of a region where the electrodes are not provided, reducing unevenness in transmittance. As a result, unevenness in the luminance of light from the touch sensor 2595 can be reduced.

Note that the shapes of the electrodes 2591 and the electrodes 2592 are not limited to the above-mentioned shapes and can be any of a variety of shapes. For example, the plurality of electrodes 2591 may be provided so that space between the electrodes 2591 are reduced as much as possible, and the plurality of electrodes 2592 may be provided with an insulating layer sandwiched between the electrodes 2591 and the electrodes 2592. In that case, between two adjacent electrodes 2592, a dummy electrode which is electrically insulated from these electrodes is preferably provided, whereby the area of a region having a different transmittance can be reduced.

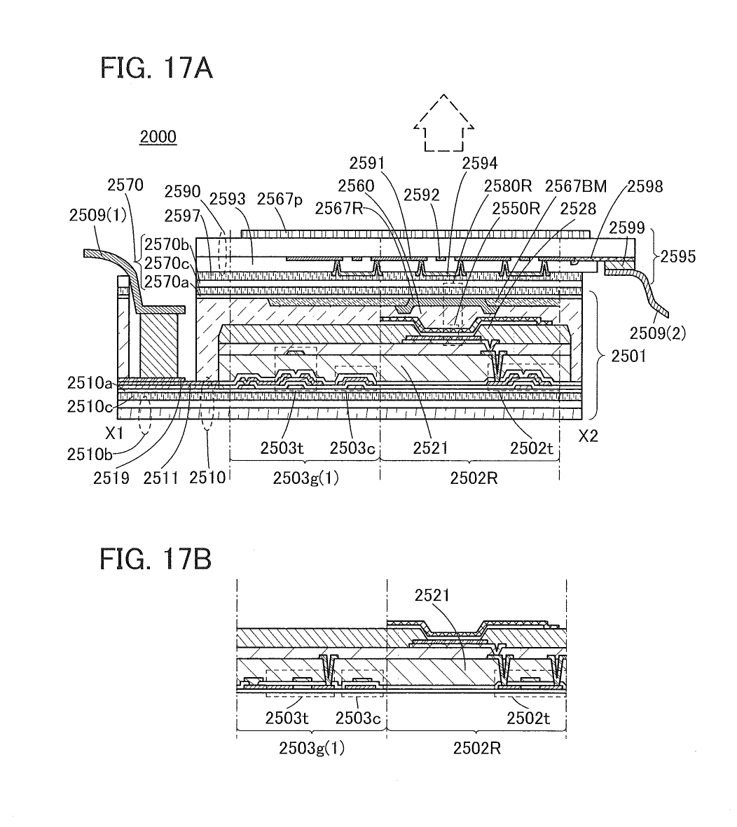

Next, the touch panel 2000 will be described in detail with reference to FIGS. 17A and 17B. FIGS. 17A and 17B are cross-sectional views taken along dashed-dotted line X1-X2 in FIG. 16A.

The touch sensor 2595 includes the electrodes 2591 and the electrodes 2592 that are provided in a staggered arrangement and on the substrate 2590, an insulating layer 2593 covering the electrodes 2591 and the electrodes 2592, and the wiring 2594 that electrically connects the adjacent electrodes 2591 to each other.

An adhesive layer 2597 is provided below the wiring 2594. The substrate 2590 is attached to the substrate 2570 with the adhesive layer 2597 so that the touch sensor 2595 overlaps with the display portion 2501.

The electrodes 2591 and the electrodes 2592 are formed using a light-transmitting conductive material. As a light-transmitting conductive material, a conductive oxide such as indium oxide, indium tin oxide, indium zinc oxide, zinc oxide, or zinc oxide to which gallium is added can be used. Note that a film containing graphene may be used as well. The film including graphene can be formed, for example, by reducing a film containing graphene oxide. As a reducing method, a method with application of heat or the like can be employed.

For example, the electrodes 2591 and the electrodes 2592 may be formed by depositing a light-transmitting conductive material on the substrate 2590 by a sputtering method and then removing an unnecessary portion by any of various patterning techniques such as photolithography.

Examples of a material for the insulating layer 2593 are a resin such as acrylic or epoxy resin, a resin having a siloxane bond, and an inorganic insulating material such as silicon oxide, silicon oxynitride, or aluminum oxide.

The wiring 2594 is formed in an opening provided in the insulating layer 2593, whereby the adjacent electrodes 2591 are electrically connected to each other. A light-transmitting conductive material can be favorably used for the wiring 2594 because the aperture ratio of the touch panel can be increased. Moreover, a material having higher conductivity than the electrodes 2591 and 2592 can be favorably used for the wiring 2594 because electric resistance can be reduced.

Through the wiring 2594, a pair of electrodes 2591 is electrically connected to each other. Between the pair of electrodes 2591, the electrode 2592 is provided.

One wiring 2598 is electrically connected to any of the electrodes 2591 and 2592. Part of the wiring 2598 serves as a terminal. For the wiring 2598, a metal material such as aluminum, gold, platinum, silver, nickel, titanium, tungsten, chromium, molybdenum, iron, cobalt, copper, or palladium or an alloy material containing any of these metal materials can be used.

Through the terminal 2599, the wiring 2598 and the FPC 2509(2) are electrically connected to each other. The terminal 2599 can be formed using any of various kinds of anisotropic conductive films (ACF), anisotropic conductive pastes (ACP), and the like.

The adhesive layer 2597 has a light-transmitting property. For example, a thermosetting resin or an ultraviolet curable resin can be used; specifically, a resin such as an acrylic-based resin, a urethane-based resin, an epoxy-based resin, or a siloxane-based resin can be used.

The display portion 2501 includes a plurality of pixels arranged in a matrix. Each of the pixels includes a display element and a pixel circuit for driving the display element.

For the substrate 2510 and the substrate 2570, for example, a flexible material having a vapor permeability of 10⁻⁵ g/(m²·day) or lower, preferably 10⁻⁶ g/(m²·day) or lower can be favorably used. Note that materials whose thermal expansion coefficients are substantially equal to each other are preferably used for the substrate 2510 and the substrate 2570 respectively. For example, the coefficient of linear expansion of the materials are preferably lower than or equal to 1×10⁻³/K, further preferably lower than or equal to 5×10⁻⁵/K, and still further preferably lower than or equal to 1×10⁻⁵/K.

A sealing layer 2560 preferably has a higher refractive index than the air. In the case where light is extracted to the sealing layer 2560 side as shown in FIGS. 17A and 17B, the sealing layer 2560 serves as an adhesive layer.

The display portion 2501 includes a pixel 2502R. The pixel 2502R includes a light-emitting module 2580R.

The pixel 2502R includes a light-emitting element 2550R and a transistor 2502t that can supply electric power to the light-emitting element 2550R. Note that the transistor 2502t functions as part of the pixel circuit. The light-emitting module 2580R includes the light-emitting element 2550R and a coloring layer 2567R.

The light-emitting element 2550R includes a lower electrode, an upper electrode, and an EL layer between the lower electrode and the upper electrode.

In the case where the sealing layer 2560 is provided on the light extraction side, the sealing layer 2560 is in contact with the light-emitting element 2550R and the coloring layer 2567R.

The coloring layer 2567R overlaps with the light-emitting element 2550R. Accordingly, part of light emitted from the light-emitting element 2550R passes through the coloring layer 2567R and is emitted to the outside of the light-emitting module 2580R as indicated by an arrow in FIG. 17A.

The display portion 2501 includes a light-blocking layer 2567BM on the light extraction side. The light-blocking layer 2567BM is provided so as to surround the coloring layer 2567R.

The display portion 2501 includes an anti-reflective layer 2567p in a region overlapping with pixels. As the anti-reflective layer 2567p, a circular polarizing plate can be used, for example.

An insulating layer 2521 is provided in the display portion 2501. The insulating layer 2521 covers the transistor 2502t. With the insulating layer 2521, unevenness caused by the pixel circuit is planarized. The insulating layer 2521 may serve also as a layer for preventing diffusion of impurities. This can prevent a reduction in the reliability of the transistor 2502t or the like due to diffusion of impurities.

The light-emitting element 2550R is formed above the insulating layer 2521. A partition 2528 is provided so as to cover end portions of the lower electrode in the light-emitting element 2550R. Note that a spacer for controlling the distance between the substrate 2510 and the substrate 2570 may be provided over the partition 2528.

A scan line driver circuit 2503g(1) includes a transistor 2503t and a capacitor 2503c. Note that the driver circuit and the pixel circuits can be formed in the same process over the same substrate.

Over the substrate 2510, the wirings 2511 through which a signal can be supplied are provided. Over the wirings 2511, the terminal 2519 is provided. The FPC 2509(1) is electrically connected to the terminal 2519. The FPC 2509(1) has a function of supplying signals such as a pixel signal and a synchronization signal. Note that a printed wiring board (PWB) may be attached to the FPC 2509(1).

For the display portion 2501, transistors with a variety of structures can be used. In the example of FIG. 17A, a bottom-gate transistor is used. In each of the transistor 2502t and the transistor 2503t illustrated in FIG. 17A, a semiconductor layer including an oxide semiconductor can be used for a channel region. Alternatively, in each of the transistor 2502t and the transistor 2503t, a semiconductor layer including amorphous silicon can be used for a channel region. Further alternatively, in each of the transistor 2502t and the transistor 2503t, a semiconductor layer including polycrystalline silicon that is obtained by crystallization process such as laser annealing can be used for a channel region.

FIG. 17B illustrates the structure of the display portion 2501 in which a top-gate transistor is used.

In the case of a top-gate transistor, a semiconductor layer including polycrystalline silicon, a single crystal silicon film that is transferred from a single crystal silicon substrate, or the like may be used for a channel region as well as the above semiconductor layers that can be used for a bottom-gate transistor.

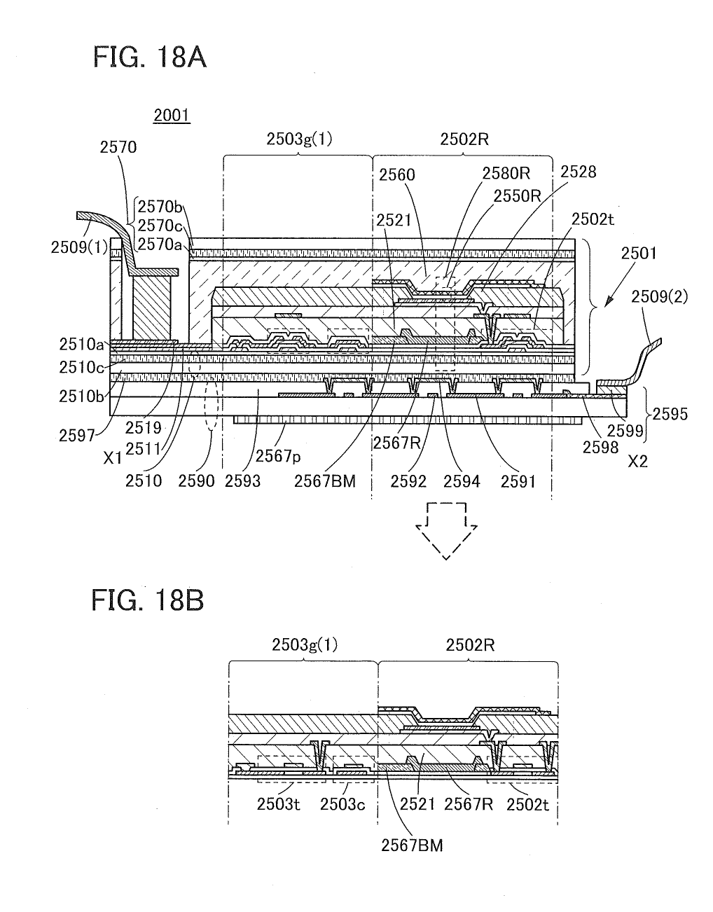

Next, a touch panel having a different structure from that illustrated in FIGS. 17A and 17B will be described with reference to FIGS. 18A and 18B.

FIGS. 18A and 18B are cross-sectional views of a touch panel 2001. In the touch panel 2001 illustrated in FIGS. 18A and 18B, the position of the touch sensor 2595 relative to the display portion 2501 is different from that in the touch panel 2000 illustrated in FIGS. 17A and 17B. Different structures will be described in detail below, and the above description of the touch panel 2000 can be referred to for the other similar structures.

The coloring layer 2567R overlaps with the light-emitting element 2550R. The light-emitting element 2550R illustrated in FIG. 18A emits light to the side where the transistor 2502t is provided. Accordingly, part of light emitted from the light-emitting element 2550R passes through the coloring layer 2567R and is emitted to the outside of the light-emitting module 2580R as indicated by an arrow in FIG. 18A.

The display portion 2501 includes the light-blocking layer 2567BM on the light extraction side. The light-shielding layer 2567BM is provided so as to surround the coloring layer 2567R.

The touch sensor 2595 is provided on the substrate 2510 side of the display portion 2501 (see FIG. 18A).

The display portion 2501 and the touch sensor 2595 are attached to each other with the adhesive layer 2597 provided between the substrate 2510 and the substrate 2590.

For the display portion 2501, transistors with a variety of structures can be used. In the example of FIG. 18A, a bottom-gate transistor is used. In the example of FIG. 18B, a top-gate transistor is used.

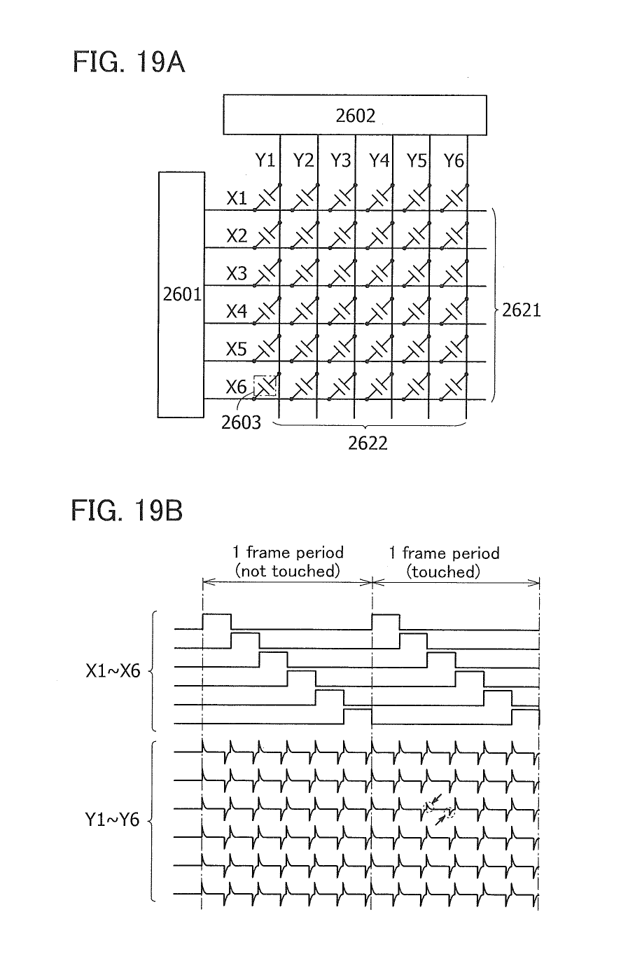

Then, an example of a method for driving the touch panel will be described with reference to FIGS. 19A and 19B.

FIG. 19A is a block diagram illustrating the structure of a mutual capacitive touch sensor. FIG. 19A illustrates a pulse voltage output circuit 2601 and a current sensing circuit 2602. Note that in the example of FIG. 19A, six wirings X1-X6 represent electrodes 2621 to which a pulse voltage is supplied, and six wirings Y1-Y6 represent electrodes 2622 that sense a change in current. FIG. 19A also illustrates a capacitor 2603 that is formed in a region where the electrodes 2621 and 2622 overlap with each other. Note that functional replacement between the electrodes 2621 and 2622 is possible.

The pulse voltage output circuit 2601 is a circuit for sequentially applying a pulse voltage to the wirings X1 to X6. By application of a pulse voltage to the wirings X1 to X6, an electric field is generated between the electrodes 2621 and 2622 of the capacitor 2603. When the electric field between the electrodes is shielded, for example, a change occurs in the capacitor 2603 (mutual capacitance). The approach or contact of a sensing target can be sensed by utilizing this change.

The current sensing circuit 2602 is a circuit for sensing changes in current flowing through the wirings Y1 to Y6 that are caused by the change in mutual capacitance in the capacitor 2603. No change in current value is sensed in the wirings Y1 to Y6 when there is no approach or contact of a sensing target, whereas a decrease in current value is sensed when mutual capacitance is decreased owing to the approach or contact of a sensing target. Note that an integrator circuit or the like is used for sensing of current.

FIG. 19B is a timing chart showing input and output waveforms in the mutual capacitive touch sensor illustrated in FIG. 19A. In FIG. 19B, sensing of a sensing target is performed in all the rows and columns in one frame period. FIG. 19B shows a period when a sensing target is not sensed (not touched) and a period when a sensing target is sensed (touched). Sensed current values of the wirings Y1 to Y6 are shown as the waveforms of voltage values.

A pulse voltage is sequentially applied to the wirings X1 to X6, and the waveforms of the wirings Y1 to Y6 change in accordance with the pulse voltage. When there is no approach or contact of a sensing target, the waveforms of the wirings Y1 to Y6 change in accordance with changes in the voltages of the wirings X1 to X6. The current value is decreased at the point of approach or contact of a sensing target and accordingly the waveform of the voltage value changes. By sensing a change in mutual capacitance in this manner, the approach or contact of a sensing target can be sensed.

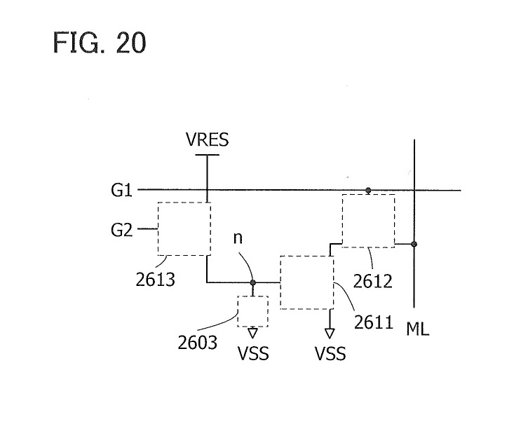

Although FIG. 19A illustrates a passive touch sensor in which only the capacitor 2603 is provided at the intersection of wirings as a touch sensor, an active touch sensor including a transistor and a capacitor may be used. FIG. 20 is a sensor circuit included in an active touch sensor.

The sensor circuit illustrated in FIG. 20 includes the capacitor 2603, a transistor 2611, a transistor 2612, and a transistor 2613.

A signal G2 is input to a gate of the transistor 2613. A voltage VRES is applied to one of a source and a drain of the transistor 2613, and one electrode of the capacitor 2603 and a gate of the transistor 2611 are electrically connected to the other of the source and the drain of the transistor 2613. One of a source and a drain of the transistor 2611 is electrically connected to one of a source and a drain of the transistor 2612, and a voltage VSS is applied to the other of the source and the drain of the transistor 2611. The signal G1 is input to a gate of the transistor 2612, and a wiring ML is electrically connected to the other of the source and the drain of the transistor 2612. The voltage VSS is applied to the other electrode of the capacitor 2603.

Next, the operation of the sensor circuit illustrated in FIG. 20 will be described. First, a potential for turning on the transistor 2613 is supplied as the signal G2, and a potential with respect to the voltage VRES is thus applied to the node n connected to the gate of the transistor 2611. Then, a potential for turning off the transistor 2613 is applied as the signal G2, whereby the potential of the node n is maintained. Then, mutual capacitance of the capacitor 2603 changes owing to the approach or contact of a sensing target such as a finger, and accordingly the potential of the node n is changed from VRES.

In reading operation, a potential for turning on the transistor 2612 is supplied as the signal G1. A current flowing through the transistor 2611, that is, a current flowing through the wiring ML is changed in accordance with the potential of the node n. By sensing this current, the approach or contact of a sensing target can be sensed.

In each of the transistors 2611, 2612, and 2613, an oxide semiconductor layer is preferably used as a semiconductor layer in which a channel region is formed. In particular, such a transistor is preferably used as the transistor 2613 so that the potential of the node n can be held for a long time and the frequency of operation of resupplying VRES to the node n (refresh operation) can be reduced.

At least part of this embodiment can be implemented in combination with any of other embodiments described in this specification as appropriate.

### Example 1

### Synthesis Example 1

In this example, synthesis of bis[3-(6-isobutyl-4-pyrimidinyl-κN3)[1]benzofuro[2,3-b]pyridin-2-yl-κC](2,8-dimethyl-4,6-nonanedionato-κ²O,O′)iridium(III) (abbreviation: [Ir(iBubfpypm)₂(divm)]) shown in Structural Formula (100) in Embodiment 1 is described as a synthesis example of the organometallic complex of one embodiment of the present invention.

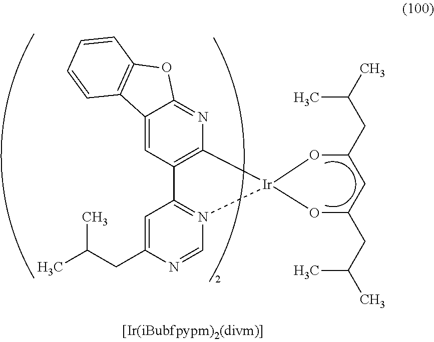

### Step 1: Synthesis of 5-chloro-3-(2-methoxyphenyl)pyridin-2-amine

First, 4.86 g of 5-chloro-3-iodopyridin-2-amine, 8.19 g of 2-methoxyphenylboronic acid, 13.2 g of potassium carbonate, 200 mL of toluene, and 100 mL of water were put into a 1-L three-neck flask equipped with a reflux pipe, and the air in the flask was replaced with nitrogen. The mixture was degassed by being stirred under reduced pressure, and then 1.11 g of tetrakis(triphenylphosphine)palladium(0) (abbreviation: Pd(PPh₃)₄) was added to the three-neck flask and the mixture was refluxed for 2.5 hours. Next, 0.55 g of Pd(PPh₃)₄ was added to the three-neck flask, and the mixture was refluxed for 9 hours to cause a reaction. Water was added to the reacted solution, and the organic layer was extracted with ethyl acetate. The obtained solution was washed with saturated saline, and magnesium sulfate was added for drying. The solution obtained by the drying was filtered. The solvent of the filtrate was distilled off, and then the resulting residue was purified by silica gel column chromatography using hexane and ethyl acetate as a developing solvent in a ratio of 2:1, so that the target pyridine derivative 5-chloro-3-(2-methoxyphenyl)pyridin-2-amine was obtained (yellow white-powder, yield of 86%). Synthesis Scheme (E1-1) of Step 1 is shown below.

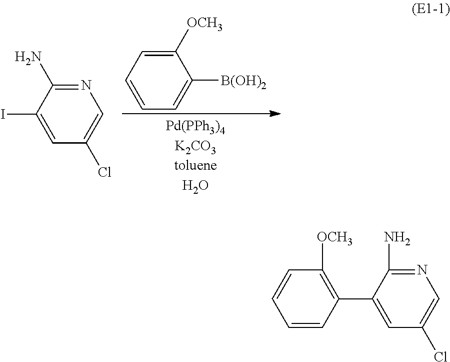

### Step 2: Synthesis of 3-chloro[1]benzofuro[2,3-b]pyridine

Next, 3.88 g of 5-chloro-3-(2-methoxyphenyl)pyridin-2-amine obtained through Step 1, 20 mL of dry THF, and 40 mL of glacial acetic acid were put into a 200-mL three-neck flask, and the air in the three-neck flask was replaced with nitrogen. The mixture in the three-neck flask was cooled down to −10° C., and 6.0 mL of tert-butyl nitrite was dripped for 10 minutes. The mixture was stirred at −10° C. for an hour and further stirred at 0° C. for 20 hours. Then, 100 mL of water was added to the resulting solution, and the precipitated solid was subjected to suction filtration. The obtained solid was purified by silica gel column chromatography using dichloromethane as a developing solvent, so that the target pyridine derivative 3-chloro[1]benzofuro[2,3-b]pyridine was obtained (white powder, yield of 59%). Synthesis Scheme (E1-2) of Step 2 is shown below.

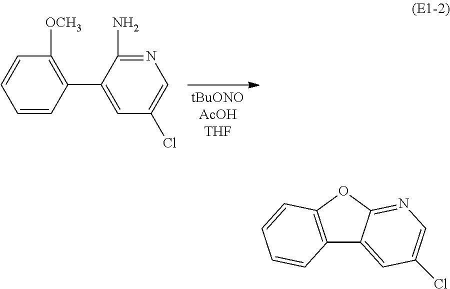 [SMILES: COc1ccccc1-c1cc(Cl)cnc1N ; Clc1cnc2oc3ccccc3c2c1]

### Step 3: Synthesis of 3-(4,4,5,5-tetramethyl-1,3,2-dioxaborolan-2-yl)[1]benzofuro[2,3-b]pyridine

Next, 3.31 g of bis(pinacolato)diboron, 1.49 g of potassium acetate, 17 mL of dry acetonitrile, 1.4 mL of a tricyclohexylphosphine solution (a 0.6M toluene solution) (abbreviation: PCy₃), and 0.37 g of tris(dibenzylideneacetone)dipalladium(0) (abbreviation: Pd₂(dba)₃) were put into a 200-mL three-neck flask, and the air in the flask was replaced with nitrogen. To this flask, a solution in which 2.14 g of 3-chloro[1]benzofuro[2,3-b]pyridine obtained through Step 2 was dissolved in 65 mL of dry acetonitrile was added, and the mixture was stirred at 86° C. for 2 hours. To the resulting solution, 0.7 mL of PCy₃ and 0.18 g of Pd₂(dba)₃ were added, and the solution was stirred at 86° C. for 8 hours. Furthermore, 0.7 mL of PCy₃ and 0.18 g of Pd₂(dba)₃ were added thereto, and the mixture was stirred at 86° C. for 4 hours and then, 0.7 mL of PCy₃ and 0.18 g of Pd₂(dba)₃ were added thereto, and the mixture was stirred at 86° C. for 7 hours. Next, water was added to the reacted solution, and the organic layer was extracted with toluene. The obtained solution was washed with saturated saline, and magnesium sulfate was added for drying. The solution obtained by the drying was filtered. The solvent of the filtrate was distilled off, and then the resulting residue was purified by silica gel column chromatography using hexane and ethyl acetate as a developing solvent in a ratio of 5:1, so that the target pyridine derivative 3-(4,4,5,5-tetramethyl-1,3,2-dioxaborolan-2-yl)[1] benzofuro[2,3-b]pyridine was obtained (white powder, yield of 46%). Synthesis Scheme (E1-3) of Step 3 is shown below.

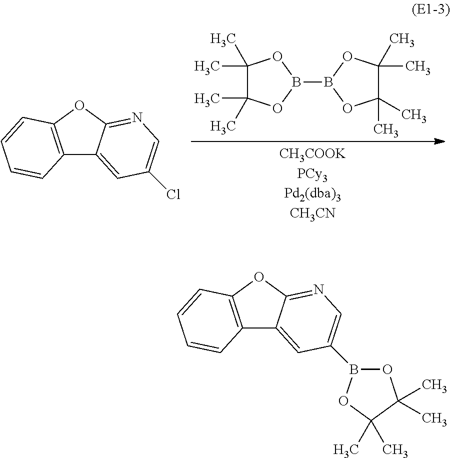

### Step 4: Synthesis of 4-isobutyl-6-([1]benzofuro[2,3-b]pyridin-3-yl)pyrimidine (abbreviation: HiBubfpypm)

Next, 2.18 g of 3-(4,4,5,5-tetramethyl-1,3,2-dioxaborolan-2-yl)[1]benzofuro[2,3-b]pyridine obtained through Step 3, 1.05 g of 4-isobutyl-6-chloropyrimidine, 10 mL of a 1M potassium acetate solution, 10 mL of a 1M sodium carbonate solution, and 30 mL of acetonitrile were put into a recovery flask equipped with a reflux pipe, and the air in the flask was replaced with argon. The mixture was degassed by being stirred under reduced pressure, and then 1.11 g of tetrakis(triphenylphosphine)palladium(0) (abbreviation: Pd(PPh₃)₄) was added thereto. The resulting mixture was irradiated with microwaves (2.45 GHz, 100 W) for 2 hours to cause a reaction. Water was added to the reacted solution, and the organic layer was extracted with dichloromethane. The obtained solution was washed with saturated saline, and magnesium sulfate was added for drying. The solution obtained by the drying was filtered. The solvent of the filtrate was distilled off, and then the resulting residue was purified by flash column chromatography using dichloromethane and ethyl acetate as a developing solvent in a ratio of 10:1, so that the target pyrimidine derivative HiBubfpypm (abbreviation) was obtained (yellow-white powder, yield of 77%). Note that the microwave irradiation was performed using a microwave synthesis system (Discover, manufactured by CEM Corporation). Synthesis Scheme (E1-4) of Step 4 is shown below.

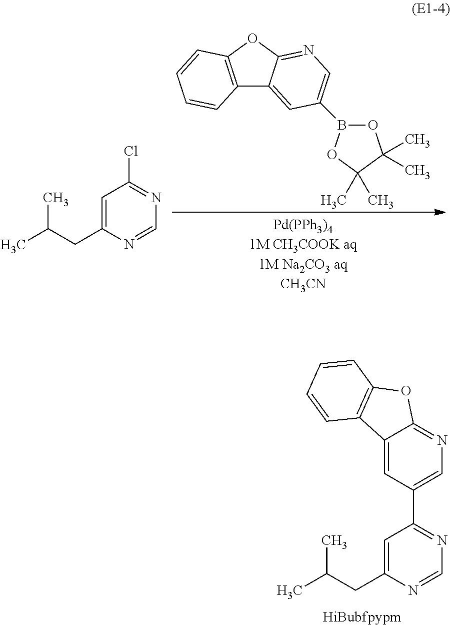 [SMILES: CC(C)Cc1cc(Cl)ncn1 ; CC1(C)OB(c2cnc3oc4ccccc4c3c2)OC1(C)C ; CC(C)Cc1cc(-c2cnc3oc4ccccc4c3c2)ncn1]

### Step 5: Synthesis of di-μ-chloro-tetrakis[3-(6-isobutyl-4-pyrimidinyl-κN3)[1]benzofuro[2,3-b]pyridin-2-yl-κC]diiridium(III) (abbreviation: [Ir(iBubfpypm)₂Cl]₂)

Next, 15 mL of 2-ethoxyethanol, 5 mL of water, 0.70 g of HiBubfpypm (abbreviation) obtained through Step 4, and 0.30 g of iridium chloride hydrate (IrCl₃.H₂O) (produced by Sigma-Aldrich Corporation) were put into a recovery flask equipped with a reflux pipe, and the air in the flask was replaced with argon. After that, microwave irradiation (2.45 GHz, 100 W) was performed for an hour to cause a reaction. After the solvent was distilled off, the residue was suction-filtered with methanol and washed to give a dinuclear complex [Ir(iBubfpypm)₂Cl]₂ (abbreviation) (yellow-brown powder, yield of 73%). Synthesis Scheme (E1-5) of Step 5 is shown below.

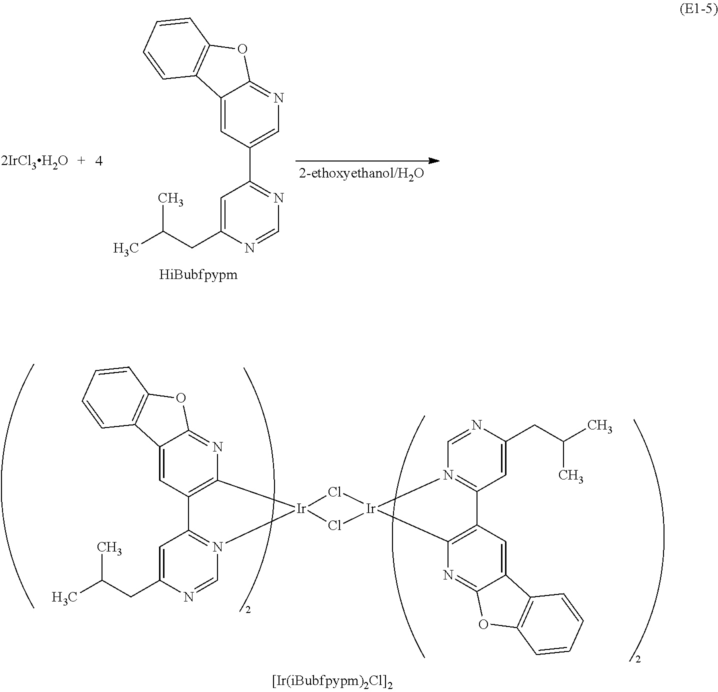

### Step 6: Synthesis of bis[3-(6-isobutyl-4-pyrimidinyl-κN3)[1]benzofuro[2,3-b]pyridin-2-yl-κC](2,8-dimethyl-4,6-nonanedionato-κ²O,O′)iridium(III) (abbreviation: [Ir(iBubfpypm)₂(divm)]

Into a recovery flask equipped with a reflux pipe were put 20 mL of 2-ethoxyethanol, 0.60 g of the dinuclear complex [Ir(iBubfpypm)₂Cl]₂ (abbreviation) obtained through Step 5, 0.20 g of 2,8-dimethyl-4,6-nonanedione (abbreviation: Hdivm), and 0.38 g of sodium carbonate. The air in the flask was replaced with argon. Then, microwave irradiation (2.45 GHz, 120 W) was performed for 60 minutes. Furthermore, 0.20 g of Hdivm was added, and the mixture was heated by microwave irradiation (2.45 GHz, 120 W) for 60 minutes. After the solvent was distilled off, the residue was dissolved in dichloromethane, and washing was performed with water and saturated saline. The obtained solution was dried with magnesium sulfate. The solution obtained by the drying was filtered. The solvent of the filtrate was distilled off, and then the resulting residue was purified by silica gel column chromatography using dichloromethane and ethyl acetate as a developing solvent in a ratio of 9:1, so that [Ir(iBubfpypm)₂(divm)] (abbreviation), which is the organometallic complex of one embodiment of the present invention, was obtained (yellow powder, yield of 6%). Synthesis Scheme (E1-6) of Step 6 is shown below.

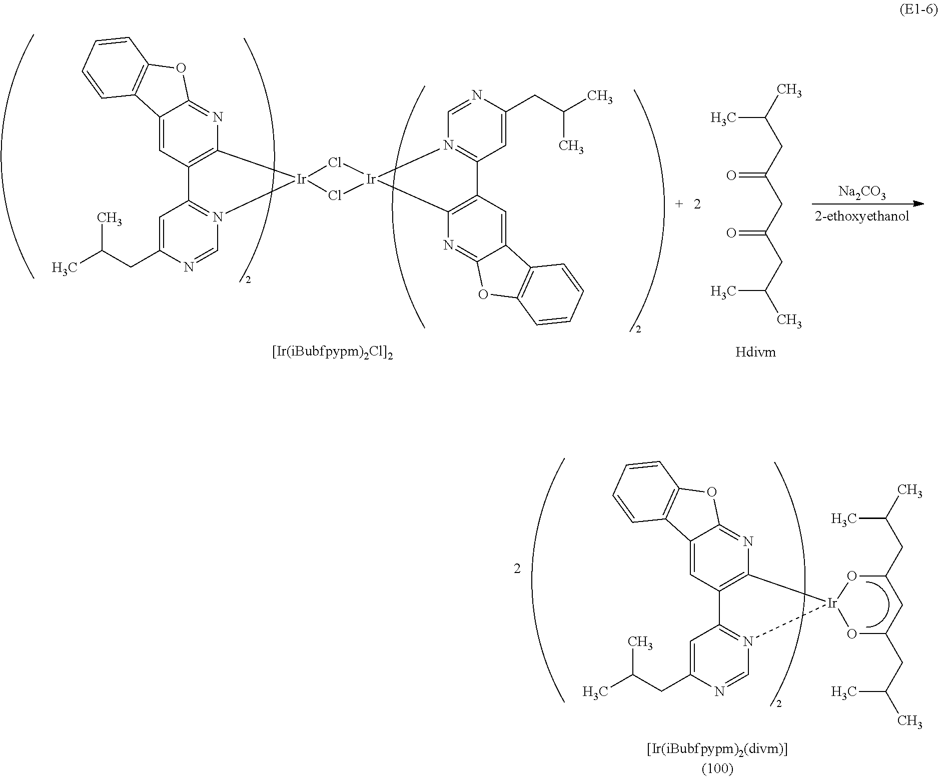

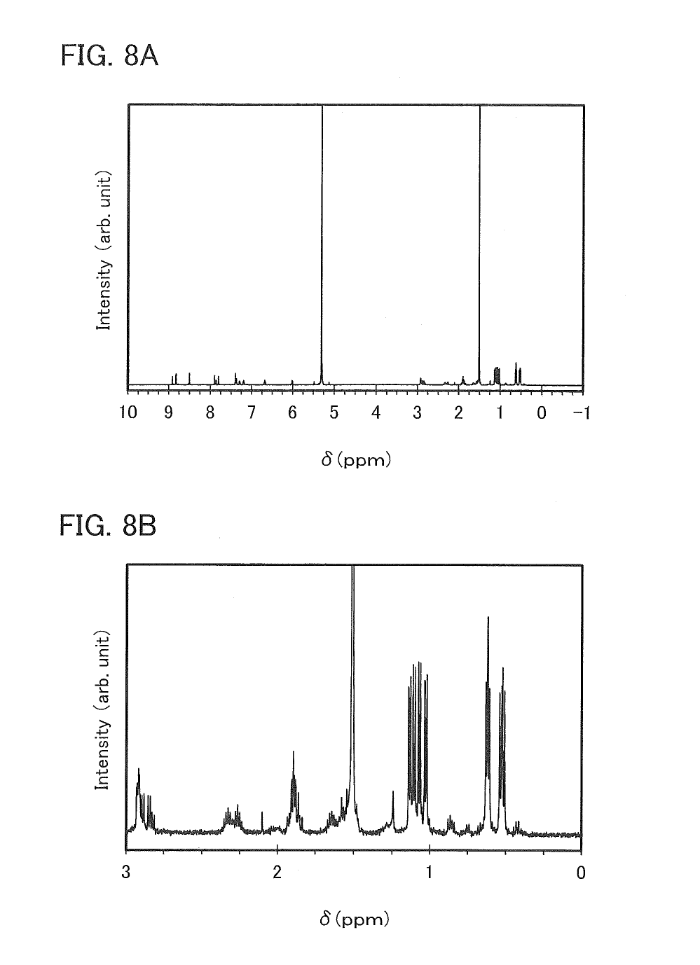

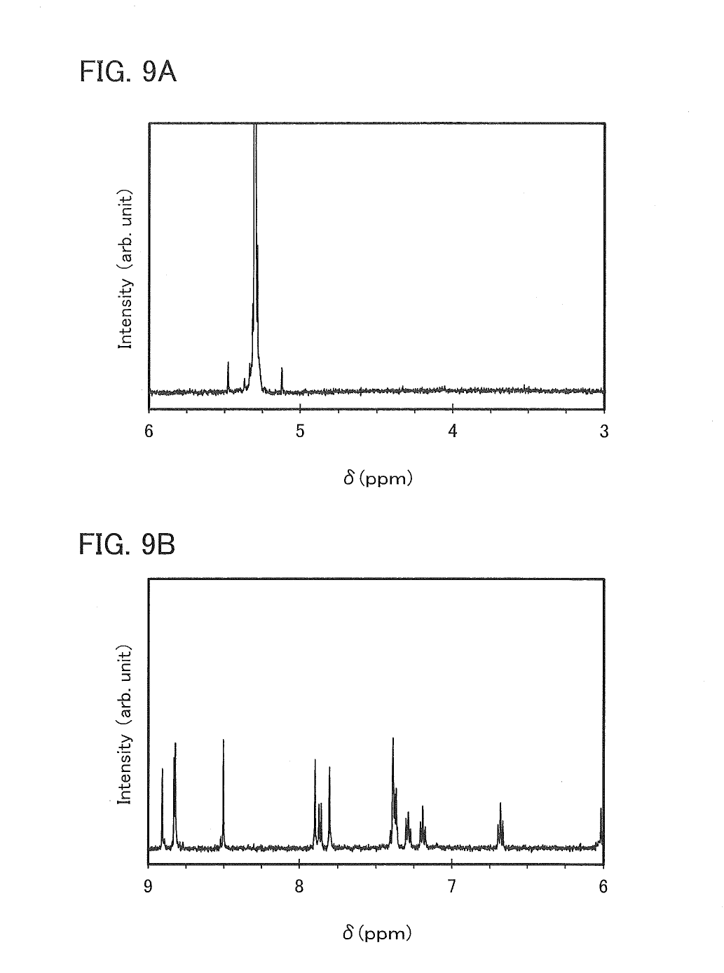

Analysis results from nuclear magnetic resonance spectroscopy (¹H NMR) of the yellow powder obtained through Step 6 are shown below. FIG. 8A is the ¹H NMR chart. FIG. 8B is an NMR chart where the range of 0 ppm to 3 ppm in FIG. 8A is enlarged, FIG. 9A is an NMR chart where the range of 3 ppm to 6 ppm in FIG. 8A is enlarged, and FIG. 9B is an NMR chart where the range of 6 ppm to 9 ppm in FIG. 8A is enlarged. These results revealed that [Ir(iBubfpypm)₂(divm)] (abbreviation), which is the organometallic complex of one embodiment of the present invention and represented by Structural Formula (100), was obtained in Synthesis Example 1.

¹H NMR. δ (CD₂Cl₂): 0.54 (t, 6H), 0.64 (t, 6H), 1.04-1.16 (m, 12H), 1.56-1.68 (m, 3H), 1.85-1.96 (m, 3H), 2.27-2.37 (m, 2H), 2.83-2.95 (m, 4H), 5.30 (s, 1H), 6.03 (d, 1H), 6.70 (t, 1H), 7.21 (t, 1H), 7.30 (t, 1H), 7.39-7.42 (m, 3H), 7.82 (s, 1H), 7.63 (d, 1H), 7.92 (s, 1H), 8.52 (s, 1H), 8.84 (d, 2H), 8.92 (s, 1H).

Next, analysis of [Ir(iBubfpypm)₂(divm)] (abbreviation) was performed by an ultraviolet-visible (UV) absorption spectrum. The ultraviolet spectrum was measured with an ultraviolet-visible spectrophotometer (V-550, manufactured by JASCO Corporation), using a dichloromethane solution (9.7 μmol/L) at room temperature.

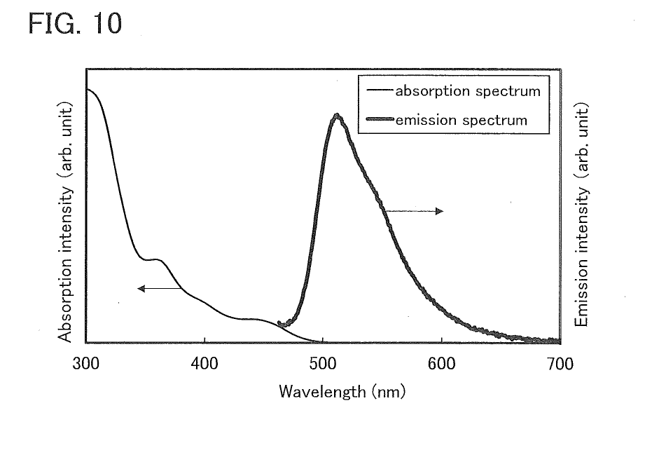

An emission spectrum of [Ir(iBubfpypm)₂(divm)] (abbreviation) was measured at room temperature, by an absolute PL quantum yields measurement system (C11347-01 manufactured by Hamamatsu Photonics K. K.). For the measurement, the deoxidized dichloromethane solution (9.7 μmol/L) was sealed in a quartz cell under a nitrogen atmosphere in a glove box (LABstar M13 (1250/780) manufactured by Bright Co., Ltd.). FIG. 10 shows the measurement results. The horizontal axis represents wavelength and the vertical axes represent molar absorption coefficient and emission intensity.

As shown in FIG. 10, [Ir(iBubfpypm)₂(divm)], which is an organometallic complex of one embodiment of the present invention, has an emission peak at 512 nm, and green light emission was observed from the dichloromethane solution.

### Example 2

### Synthesis Example 2

In this example, synthesis of bis[3-(6-isobutyl-4-pyrimidinyl-κN3)[1]benzothieno[2,3-b]pyridin-2-yl-κC](2,4-pentan edionato-κ²O,O′)iridium(III) (abbreviation: [Ir(iBubtpypm)₂(acac)]) shown in Structural Formula (110) in Embodiment 1 is described in detail as an example of synthesizing the organometallic complex of one embodiment of the present invention.

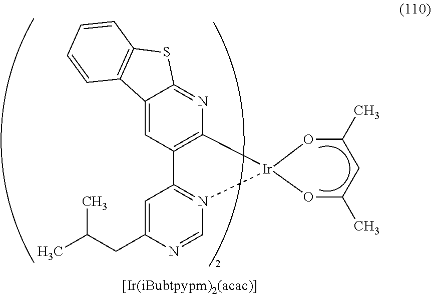

### Step 1: Synthesis of 5-chloro-3-(2-methylthiophenyl)pyridin-2-amine

First, 4.99 g of 5-chloro-3-iodopyridin-2-amine, 5.00 g of 2-methylthiophenylboronic acid, 8.32 g of potassium carbonate, 200 mL of toluene, and 100 mL of water were put into a 1-L three-neck flask equipped with a reflux pipe, and the air in the flask was replaced with nitrogen. The mixture was degassed by being stirred under reduced pressure, and then 1.10 g of tetrakis(triphenylphosphine)palladium(0) (abbreviation: Pd(PPh₃)₄) was added and the mixture was refluxed for 2 hours. Then, 0.55 g of Pd(PPh₃)₄ was added, and the mixture was refluxed for 8.5 hours. Furthermore, 0.55 g of Pd(PPh₃)₄ was added, and the mixture was refluxed for 8 hours. Then, 4.96 g of 2-methylthiophenylboronic acid, 4.11 g of potassium carbonate, and 0.55 g of Pd(PPh₃)₄ were added, and the mixture was refluxed for 8 hours to cause a reaction. Water was added to the reacted solution, and the organic layer was extracted with ethyl acetate. The obtained solution was washed with saturated saline, and magnesium sulfate was added for drying. The solution obtained by the drying was filtered. The solvent of the filtrate was distilled off, and then the resulting residue was purified by silica gel column chromatography using hexane and ethyl acetate as a developing solvent in a ratio of 2:1, so that the target pyridine derivative 5-chloro-3-(2-methylthiophenyl)pyridin-2-amine was obtained (yellow white powder, yield of 81%). Synthesis Scheme (E2-1) of Step 1 is shown below.

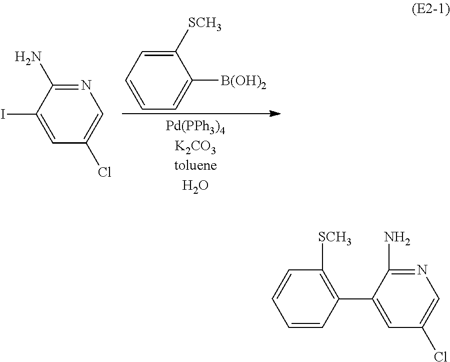

### Step 2: Synthesis of 3-chloro[1]benzothieno[2,3-b]pyridine

Next, 3.98 g of 5-chloro-3-(2-methylthiophenyl)pyridin-2-amine obtained through Step 1, 20 mL of dry THF, and 40 mL of glacial acetic acid were put into a 300-mL three-neck flask, and the air in the three-neck flask was replaced with nitrogen. The mixture in the three-neck flask was cooled down to −10° C., and 5.7 mL of tert-butyl nitrite was dripped for 10 minutes. The mixture was stirred at −10° C. for an hour and further stirred at 0° C. for 19 hours. Then, 100 mL of water was added to the resulting solution, and the precipitated solid was subjected to suction filtration. The obtained solid was purified by flash column chromatography using dichloromethane as a developing solvent, so that the target pyridine derivative 3-chloro[1]benzothieno[2,3-b]pyridine was obtained (white powder, yield of 49%). Synthesis Scheme (E2-2) of Step 2 is shown below.

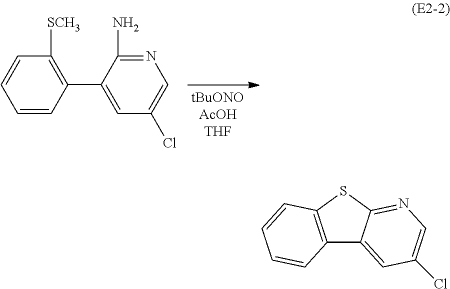 [SMILES: CSc1ccccc1-c1cc(Cl)cnc1N ; Clc1cnc2sc3ccccc3c2c1]

### Step 3: Synthesis of 3-(4,4,5,5-tetramethyl-1,3,2-dioxaborolan-2-yl)[1]benzothieno[2,3-b]pyridine

Next, 2.52 g of bis(pinacolato)diboron, 1.20 g of potassium acetate, 13 mL of dry acetonitrile, 1.0 mL of a tricyclohexylphosphine solution (a 0.6M toluene solution) (abbreviation: PCy₃), and 0.28 g of tris(dibenzylideneacetone)dipalladium(0) (abbreviation: Pd₂(dba)₃) were put into a 200-mL three-neck flask, and the air in the flask was replaced with nitrogen. To this flask, a solution in which 1.70 g of 3-chloro[l]benzothieno[2,3-b]pyridine obtained through Step 2 is dissolved in 51 mL of dry acetonitrile was added, and the mixture was stirred at 86° C. for 6 hours. To the resulting solution, 0.5 mL of PCy₃ and 0.14 g of Pd₂(dba)₃ were added, and the solution was stirred at 86° C. for 7.5 hours. Furthermore, 0.5 mL of PCy₃ and 0.14 g of Pd₂(dba)₃ were added thereto, and the mixture was stirred at 86° C. for 7.5 hours. Water was added to the reacted solution, and the organic layer was extracted with ethyl acetate. The obtained solution was washed with saturated saline, and magnesium sulfate was added for drying. The solution obtained by the drying was filtered. The solvent of the filtrate was distilled off, and then the resulting residue was purified by silica gel column chromatography using hexane and ethyl acetate as a developing solvent in a ratio of 5:1. The obtained fraction was concentrated to give a solid. This solid was purified by silica gel column chromatography using toluene and ethyl acetate as a developing solvent in a ratio of 10:1, so that target pyridine derivative 3-(4,4,5,5-tetramethyl-1,3,2-dioxaborolan-2-yl)[1]benzothieno[2,3-b]pyridine was obtained (white powder, yield of 58%). Synthesis Scheme (E2-3) of Step 3 is shown below.

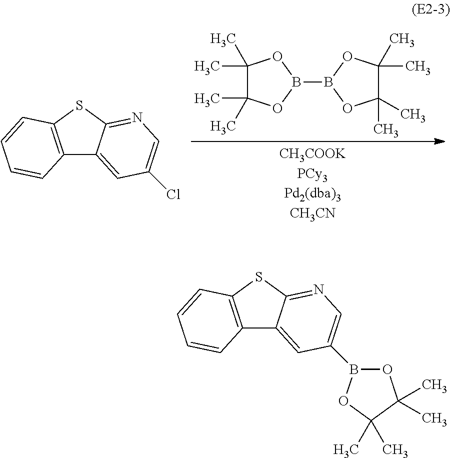

### Step 4: Synthesis of 4-isobutyl-6-([1]benzothieno[2,3-b]pyridin-3-yl)pyrimidine (abbreviation: HiBubtpypm)

Next, 2.76 g of 3-(4,4,5,5-tetramethyl-1,3,2-dioxaborolan-2-yl)[1]benzothieno[2,3-b]pyridine obtained through Step 3, 1.27 g of 4-isobutyl-6-chloropyrimidine, 12 mL of a 1M potassium acetate solution, 12 mL of a 1M sodium carbonate solution, and 32 mL of acetonitrile were put into a recovery flask equipped with a reflux pipe, and the air in the flask was replaced with argon. The mixture was degassed by being stirred under reduced pressure, and then 0.48 g of tetrakis(triphenylphosphine)palladium(0) (abbreviation: Pd(PPh₃)₄) was added thereto. The mixture was irradiated with microwaves (2.45 GHz, 100 W) for 1.5 hours to cause a reaction. Water was added to the reacted solution, and the organic layer was extracted with ethyl acetate. The obtained solution was washed with saturated saline, and magnesium sulfate was added for drying. The solution obtained by the drying was filtered. The solvent of the filtrate was distilled off, and then the resulting residue was purified by silica gel column chromatography using dichloromethane and ethyl acetate as a developing solvent in a ratio of 6:1, so that a pyrimidine derivative HiBubtpypm (abbreviation), which was the target substance, was obtained (white powder, yield of 70%). Note that the microwave irradiation was performed using a microwave synthesis system (Discover, manufactured by CEM Corporation). Synthesis Scheme (E2-4) of Step 4 is shown below.

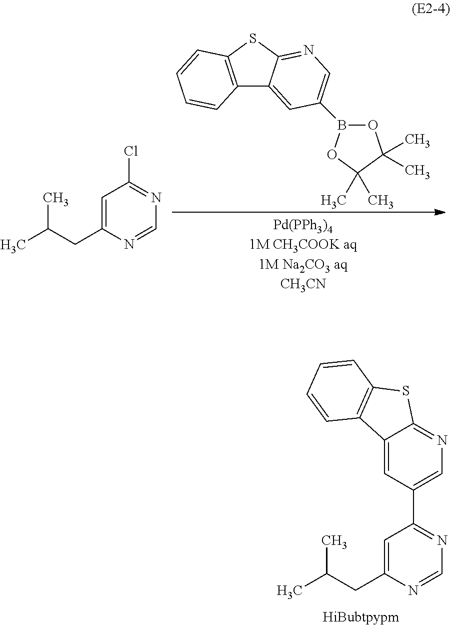 [SMILES: CC(C)Cc1cc(Cl)ncn1 ; CC1(C)OB(c2cnc3sc4ccccc4c3c2)OC1(C)C ; CC(C)Cc1cc(-c2cnc3sc4ccccc4c3c2)ncn1]

### Step 5: Synthesis of di-μ-chloro-tetrakis[3-(6-isobutyl-4-pyrimidinyl-κN3)[1]benzothieno[2,3-b]pyridin-2-yl-κC]diiridium(III) (abbreviation: [Ir(iBubtpypm)₂Cl]₂)

Next, 15 mL of 2-ethoxyethanol, 5 mL of water, 0.81 g of HiBubtpypm (abbreviation) obtained through Step 4, and 0.36 g of iridium chloride hydrate (IrCl₃.H₂O) (produced by Sigma-Aldrich Corporation) were put into a recovery flask equipped with a reflux pipe, and the air in the flask was replaced with argon. After that, microwave irradiation (2.45 GHz, 100 W) was performed for an hour to cause a reaction. The mixture was suction-filtered, and washing was performed with methanol to give a dinuclear complex [Ir(iBubtpypm)₂Cl]₂ (abbreviation) (orange-brown powder, yield of 72%). Synthesis Scheme (E2-5) of Step 5 is shown below.

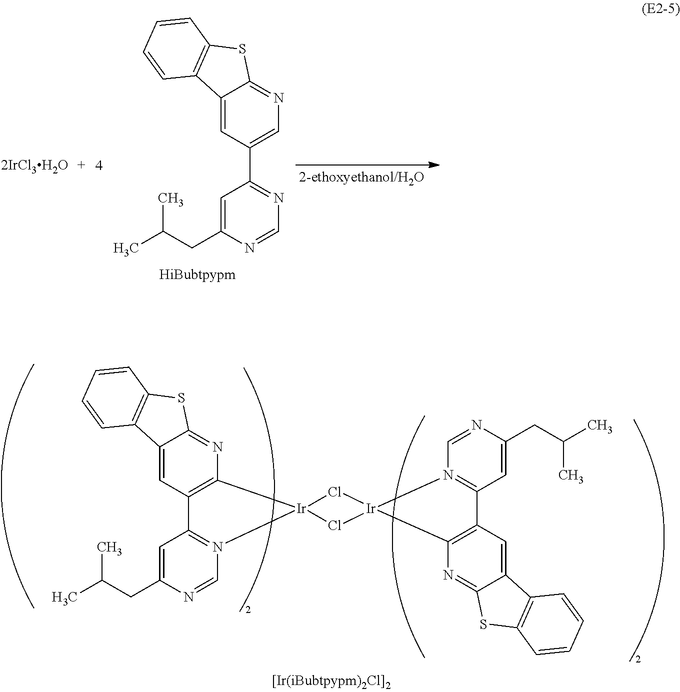

### Step 6: Synthesis of bis[3-(6-isobutyl-4-pyrimidinyl-κN3)[1]benzothieno[2,3-b]pyridin-2-yl-κC](2,4-pentan edionato-κ²O, O′)iridium(III) (abbreviation: [Ir(iBubtpypm)₂(acac)])

Into a recovery flask equipped with a reflux pipe were put 20 mL of 2-ethoxyethanol, 0.71 g of the dinuclear complex [Ir(iBubtpypm)₂Cl]₂ (abbreviation) obtained through Step 5, 0.13 g of 2,4-pentanedione (abbreviation: Hacac), and 0.46 g of sodium carbonate. The air in the flask was replaced with argon. Then, microwave irradiation (2.45 GHz, 100 W) was performed for 60 minutes. Furthermore, 0.13 g of Hacac was added, and the mixture was heated by microwave irradiation (2.45 GHz, 100 W) for 60 minutes. The obtained mixture was suction-filtered with dichloromethane, and the obtained filtrate was concentrated. The obtained solid was purified by silica gel column chromatography using dichloromethane and ethyl acetate as a developing solvent in a ratio of 4:1. The obtained fraction was concentrated to give a solid. This solid was purified by flash column chromatography (amino-modified silica gel) using dichloromethane and hexane as a developing solvent in a ratio of 1:1, so that [Ir(iBubtpypm)₂(acac)] (abbreviation), which is the organometallic complex of one embodiment of the present invention, was obtained (yellow powder, yield of 0.4%). Synthesis Scheme (E2-6) of Step 6 is shown below.

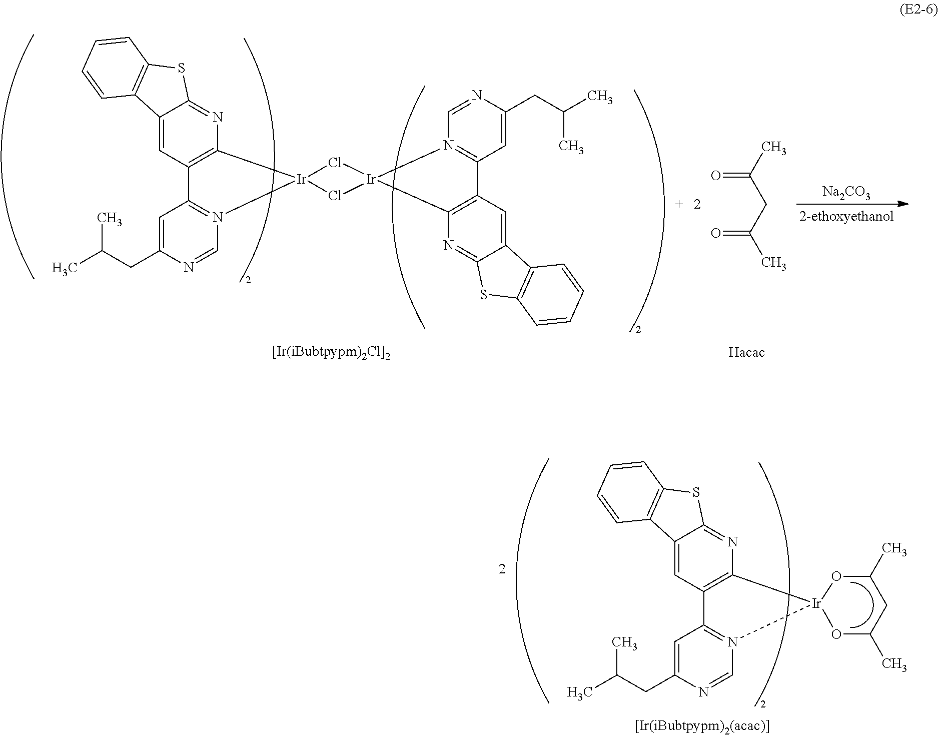

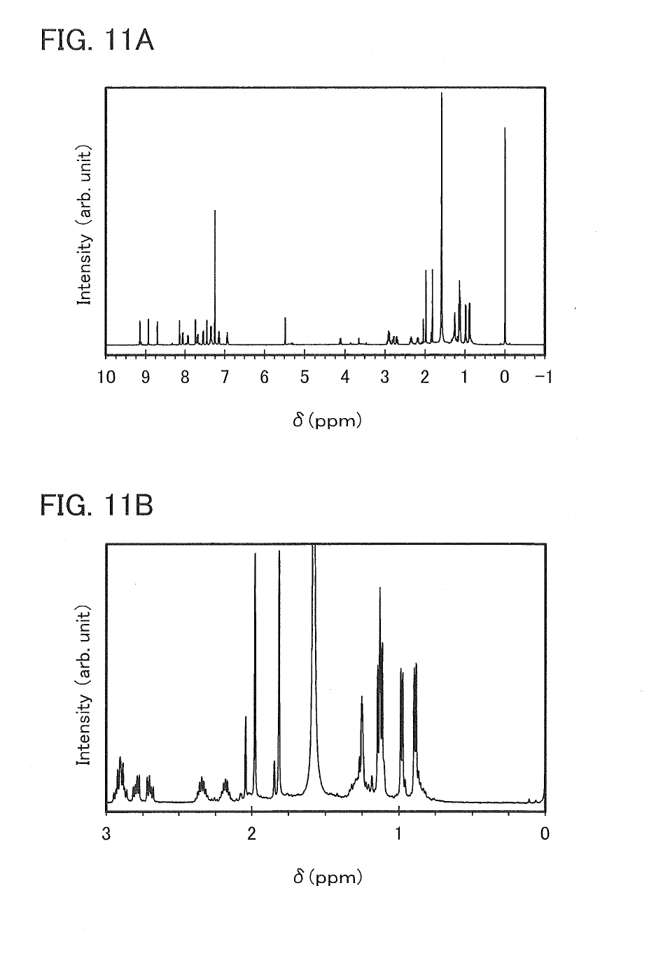

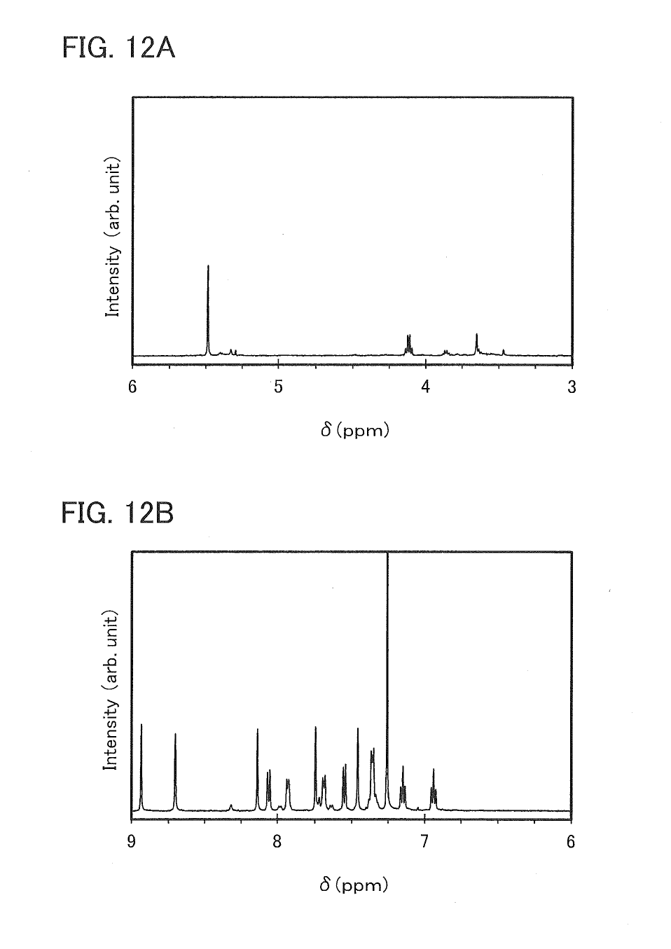

Analysis results from nuclear magnetic resonance spectroscopy (¹H NMR) of the yellow powder obtained through Step 6 are shown below. FIG. 11A is the ¹H NMR chart. FIG. 11B is an NMR chart where the range of 0 ppm to 3 ppm in FIG. 11A is enlarged, FIG. 12A is an NMR chart where the range of 3 ppm to 6 ppm in FIG. 11A is enlarged, and FIG. 12B is an NMR chart where the range of 6 ppm to 9 ppm in FIG. 11A is enlarged. These results revealed that [Ir(iBubtpypm)₂(acac)] (abbreviation), which is the organometallic complex of one embodiment of the present invention and represented by Structural Formula (110), was obtained in Synthesis Example 2.

¹H NMR. δ (CDCl₃): 0.89 (d, 3H), 0.99 (d, 3H), 1.12-1.15 (m, 6H), 1.82 (s, 3H), 1.99 (s, 3H), 2.16-2.21 (m, 1H), 2.31-2.38 (m, 1H), 2.69-2.73 (m, 1H), 2.78-2.82 (m, 1H), 2.87-2.96 (m, 2H), 5.49 (s, 1H), 6.95 (t, 1H), 7.16 (t, 1H), 7.3-7.37 (m, 2H), 7.47 (s, 1H), 7.56 (d, 1H), 7.70 (d, 1H), 7.75 (s, 1H), 7.94 (d, 1H), 8.07 (d, 1H), 8.14 (s, 111), 8.71 (s, 1H), 8.94 (s, 1H), 9.16 (s, 1H).

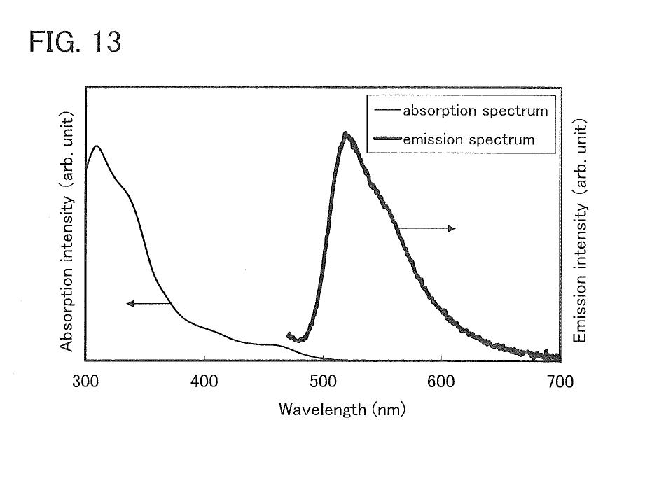

Next, analysis of [Ir(iBubtpypm)₂(acac)] (abbreviation) was performed by an ultraviolet-visible (UV) absorption spectrum. The ultraviolet spectrum was measured with an ultraviolet-visible spectrophotometer (V-550, manufactured by JASCO Corporation), using a dichloromethane solution (0.010 mmol/L) at room temperature. Furthermore, an emission spectrum of [Ir(iBubtpypm)₂(acac)] (abbreviation) was measured at room temperature, by an absolute PL quantum yields measurement system (C11347-01 manufactured by Hamamatsu Photonics K. K.). For the measurement, the deoxidized dichloromethane solution (0.010 mmol/L) was sealed in a quartz cell under a nitrogen atmosphere in a glove box (LABstar M13 (1250/780) manufactured by Bright Co., Ltd.). FIG. 13 shows the measurement results. The horizontal axis represents wavelength and the vertical axes represent molar absorption coefficient and emission intensity.

As shown in FIG. 13, [Ir(iBubtpypm)₂(acac)], which is an organometallic complex of one embodiment of the present invention, has an emission peak at 519 nm, and green light emission was observed from the dichloromethane solution.

This application is based on Japanese Patent Application serial no. 2014-201359 filed with Japan Patent Office on Sep. 30, 2014, the entire contents of which are hereby incorporated by reference.

What is claimed is:

1. An organometallic complex comprising:
a metal belonging to Group 9 or 10; and
a ligand,
wherein the ligand comprises a benzofuro[2,3-b]pyridine skeleton or a benzothieno[2,3-b]pyridine skeleton, and a pyrimidine ring,
wherein carbon at the 2-position of the benzofuro[2,3-b]pyridine skeleton or the benzothieno[2,3-b]pyridine skeleton is bonded to the metal,
wherein nitrogen at the 3-position of the pyrimidine ring is bonded to the metal,
wherein carbon at the 3-position of the benzofuro[2,3-b]pyridine skeleton or the benzothieno[2,3-b]pyridine skeleton is bonded to carbon at the 4-position of the pyrimidine ring, and
wherein carbon at the 6-position of the pyrimidine ring is bonded to an alkyl group or an aryl group.

2. The organometallic complex according to claim 1, wherein the alkyl group is a substituted or unsubstituted alkyl group having 4 to 10 carbon atoms.

3. The organometallic complex according to claim 1, wherein the alkyl group has a branched carbon chain.

4. The organometallic complex according to claim 1, wherein the metal is iridium.

5. The organometallic complex according to claim 1, further comprising a monoanionic bidentate chelate ligand having a beta-diketone structure, a monoanionic bidentate chelate ligand having a carboxyl group, a monoanionic bidentate chelate ligand having a phenolic hydroxyl group, or a monoanionic bidentate chelate ligand in which two ligand elements are both nitrogen.

6. A light-emitting element comprising the organometallic complex according to claim 1 in an EL layer.

7. The light-emitting element according to claim 6, wherein the EL layer is configured to emit phosphorescence.

8. A display device comprising:
the light-emitting element according to claim 6; and
a driver.

9. A lighting device comprising:
the light-emitting element according to claim 6; and
an operation switch.

10. A light-emitting device comprising:
the light-emitting element according to claim 6; and
an operation switch.

11. An electronic device comprising:
the light-emitting element according to claim 6; and
a power supply switch.

12. An organometallic complex represented by General Formula (G1): 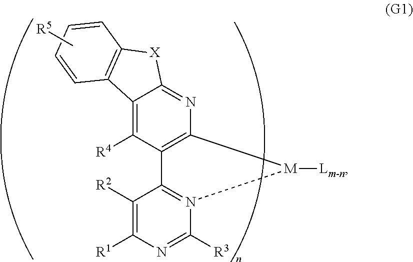
wherein:
L represents a monoanionic ligand;
R¹ represents a substituted or unsubstituted alkyl group having 1 to 10 carbon atoms or a substituted or unsubstituted aryl group having 6 to 13 carbon atoms;
each of R² to R⁵ independently represents hydrogen, a substituted or unsubstituted alkyl group having 1 to 6 carbon atoms or a substituted or unsubstituted phenyl group;
the organometallic complex is monosubstituted, disubstituted, trisubstituted, tetrasubstituted, or unsubstituted by the R⁵;
X represents O, S, or Se;
M represents a metal belonging to Group 9 or 10;
when M represents a metal belonging to Group 9, in is 3 and n is any one of 1 to 3; and
when M represents a metal belonging to Group 10, in is 2 and n is 1 or 2.

13. The organometallic complex according to claim 12, wherein the R¹ represents a substituted or unsubstituted alkyl group having 4 to 10 carbon atoms.

14. The organometallic complex according to claim 12, wherein the R¹ represents an alkyl group having a branched carbon chain.

15. The organometallic complex according to claim 12, wherein the L represents a monoanionic bidentate chelate ligand having a beta-diketone structure, a monoanionic bidentate chelate ligand having a carboxyl group, a monoanionic bidentate chelate ligand having a phenolic hydroxyl group, or a monoanionic bidentate chelate ligand in which two ligand elements are both nitrogen.

16. The organometallic complex according to claim 12, wherein the L is represented by any one of General Formulae (L1) to (L7): 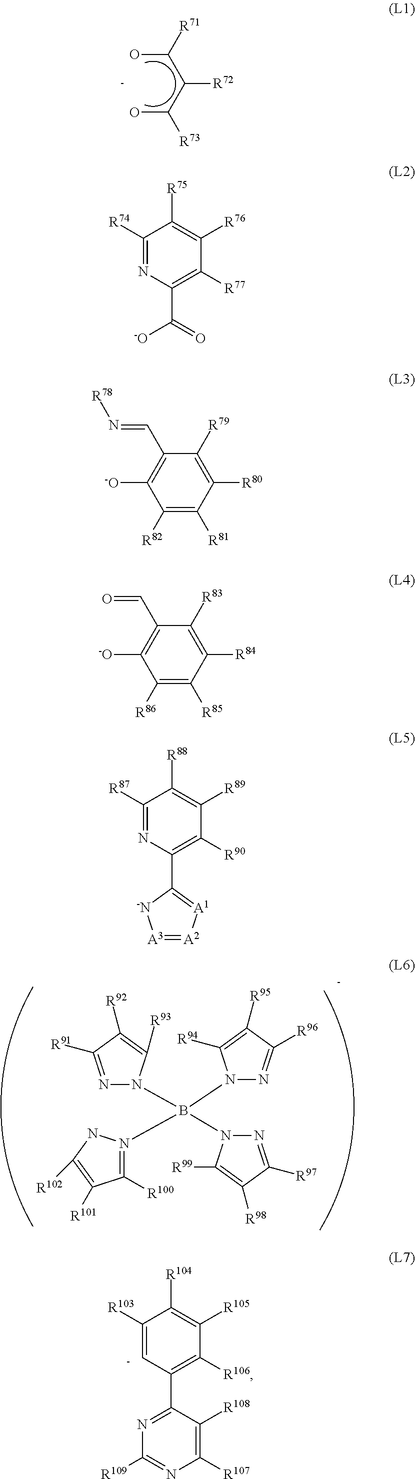
wherein:
each of R⁷¹ to R¹⁰⁹ independently represents hydrogen, a substituted or unsubstituted alkyl group having 1 to 6 carbon atoms, a halogen group, a vinyl group, a substituted or unsubstituted haloalkyl group having 1 to 6 carbon atoms, a substituted or unsubstituted alkoxy group having 1 to 6 carbon atoms, or a substituted or unsubstituted alkylthio group having 1 to 6 carbon atoms;
each of A¹ to A³ independently represents nitrogen, sp² carbon bonded to hydrogen, or sp² carbon bonded to a substituent R; and
the substituent R represents an alkyl group having 1 to 6 carbon atoms, a halogen group, a haloalkyl group having 1 to 6 carbon atoms, or a phenyl group.

17. A light-emitting element comprising the organometallic complex according to claim 12 in an EL layer.

18. The light-emitting element according to claim 17, wherein the EL layer is configured to emit phosphorescence.

19. A display device comprising:
the light-emitting element according to claim 17; and
a driver.

20. A lighting device comprising:
the light-emitting element according to claim 17; and
an operation switch.

21. A light-emitting device comprising:
the light-emitting element according to claim 17; and
an operation switch.

22. An electronic device comprising:
the light-emitting element according to claim 17; and
a power supply switch.

23. An organometallic complex represented by General Formula (G2): 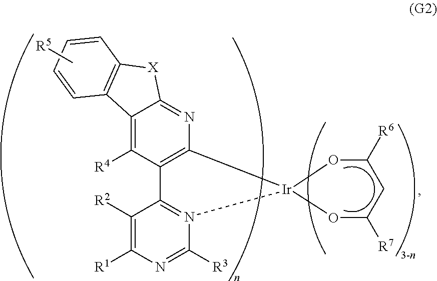
wherein:
L represents a monoanionic ligand;
R¹ represents a substituted or unsubstituted alkyl group having 1 to 10 carbon atoms or a substituted or unsubstituted aryl group having 6 to 13 carbon atoms;
each of R² to R⁷ independently represents hydrogen, a substituted or unsubstituted alkyl group having 1 to 6 carbon atoms or a substituted or unsubstituted phenyl group;
the organometallic complex is monosubstituted, disubstituted, trisubstituted, tetrasubstituted, or unsubstituted by the R⁵;
X represents O, S, or Se; and
n is any one of 1 to 3.

24. The organometallic complex according to claim 23, wherein the organometallic complex is represented by Structural Formula (100):

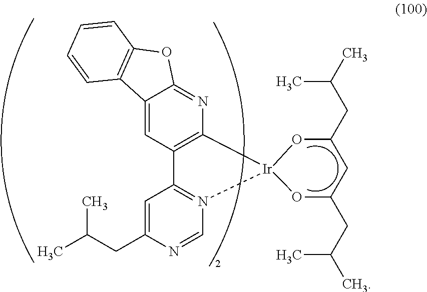

25. The organometallic complex according to claim 23, wherein the organometallic complex is represented by Structural Formula (110):

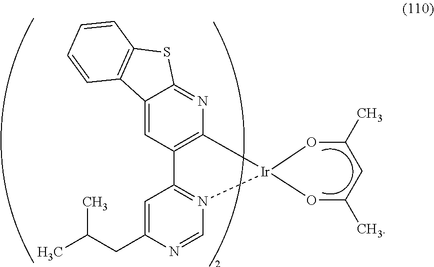

26. A light-emitting element comprising the organometallic complex according to claim 23 in an EL layer.

27. The light-emitting element according to claim 26, wherein the EL layer is configured to emit phosphorescence.

28. A display device comprising:
the light-emitting element according to claim 26; and
a driver.

29. A lighting device comprising:
the light-emitting element according to claim 26; and
an operation switch.

30. A light-emitting device comprising:
the light-emitting element according to claim 26; and
an operation switch.

31. An electronic device comprising:
the light-emitting element according to claim 26; and
a power supply switch.
